(19) United States
(12) Patent Application Publication
(10) Pub. No.: US 2024/0154079 A1
(43) Pub. Date: May 9, 2024

(54) DISPLAY DEVICE

(71) Applicant: Samsung Display Co., Ltd., Yongin-si (KR)

(72) Inventors: Hyun Eok SHIN, Yongin-si (KR); Ju Hyun LEE, Yongin-si (KR); Sung Joo KWON, Yongin-si (KR); Joon Yong PARK, Yongin-si (KR)

(73) Assignee: Samsung Display Co., Ltd., Yongin-si (KR)

(21) Appl. No.: 18/497,140

(22) Filed: Oct. 30, 2023

(30) Foreign Application Priority Data
Nov. 9, 2022 (KR) 10-2022-0148962

(51) Int. Cl. H01L 33/62; H01L 25/16; H01L 33/60

(52) U.S. Cl. CPC H01L 33/62; H01L 25/167; H01L 33/60

(57) ABSTRACT

A display device includes a first electrode and a second electrode that are disposed on a substrate and spaced apart from each other. A light emitting element is disposed between the first electrode and the second electrode. A first pixel electrode is disposed on the first electrode, and is electrically connected to a first end portion of the light emitting element and the first electrode. A second pixel electrode is disposed on the second electrode, and is electrically connected to a second end portion of the light emitting element. Each of the first electrode and the second electrode includes a multi-layer structure including a first layer and a second layer disposed on the first layer. The first layer includes a metal reflecting light. The second layer includes tungsten oxide.

### CROSS-REFERENCE TO RELATED APPLICATION(S)

This application claims priority to and benefits of Korean patent application No. 10-2022-0148962 under 35 U.S.C. § 119, filed on Nov. 9, 2022 in the Korean Intellectual Property Office, the entire contents of which are incorporated herein by reference.

### BACKGROUND

### 1. Technical Field

The disclosure relates to a display device.

### 2. Description of the Related Art

As interest in information displays and demand for portable information media increase, research and commercialization has focused on display devices.

### SUMMARY

Embodiments provide a display device capable of decreasing a contact resistance and a resistive-capacitive (RC) delay.

In accordance with an aspect of the disclosure, a display device may include a first electrode and a second electrode that are disposed on a substrate and spaced apart from each other, a light emitting element disposed between the first electrode and the second electrode, a first pixel electrode disposed on the first electrode, the first pixel electrode being electrically connected to a first end portion of the light emitting element and the first electrode, and a second pixel electrode disposed on the second electrode, the second pixel electrode being electrically connected to a second end portion of the light emitting element. Each of the first electrode and the second electrode may include a multi-layer structure including a first layer and a second layer disposed on the first layer. The first layer may include a metal reflecting light. The second layer may include tungsten oxide.

The first pixel electrode may include at least one of indium tin oxide (ITO), indium zinc oxide (IZO), zinc oxide (ZnOₓ), and indium gallium zinc oxide (IGZO). The first pixel electrode may be in direct contact with the second layer of the first electrode.

The first layer may include aluminum. The first layer may not include any alloy.

The second layer may have a thickness in a range of about 50 Å to about 300 Å.

The first layer may have a thickness in a range of about 500 Å to about 2000 Å.

Each of the first electrode and the second electrode may further include a third layer disposed under the first layer. The third layer and the first layer may include a same material.

The display device may further include an insulating layer disposed under the first electrode and the second electrode, and a metal layer disposed between the substrate and the insulating layer. The first electrode may be in electrical contact with the metal layer through a contact hole penetrating the insulating layer.

The metal layer may have a multi-layer structure including a fourth layer and a fifth layer disposed on the fourth layer. The fourth layer may include a material having an electrical conductivity higher than an electrical conductivity of the fifth layer. The fifth layer of the metal layer may be in direct contact with the third layer of the first electrode.

The metal layer may include a multi-layer structure including a fourth layer and a sixth layer disposed under the fourth layer. The fourth layer may include a material having an electrical conductivity higher than an electrical conductivity of the sixth layer. The fourth layer of the metal layer may be in direct contact with the third layer of the first electrode.

The display device may further include an insulating layer disposed under the first electrode and the second electrode, and a metal layer disposed between the substrate and the insulating layer. The first electrode may be in electrical contact with the metal layer through a contact hole penetrating the insulating layer.

The metal layer may include a multi-layer structure including a fourth layer and a fifth layer disposed on the fourth layer. The fourth layer may include a material having an electrical conductivity higher than an electrical conductivity of the fifth layer. The fifth layer of the metal layer may be in direct contact with the first layer of the first electrode.

The display device may further include a color conversion layer disposed above the light emitting element, the color conversion layer converting a wavelength of light incident from the light emitting element.

In accordance with another aspect of the disclosure, a display device may include a pixel disposed in a display area, and a pad disposed in a non-display area located at a side of the display area. The pad may include a first pad electrode disposed on a metal layer, and a second pad electrode disposed on the first pad electrode. The first pad electrode may include a multi-layer structure including a first layer and a second layer disposed on the first layer. The first layer may include a metal reflecting light. The second layer may include tungsten oxide.

The second pad electrode may include at least one of indium tin oxide (ITO), indium zinc oxide (IZO), zinc oxide (ZnOₓ), and indium gallium zinc oxide (IGZO). The second pad electrode may be in direct contact with the second layer of the first pad electrode.

The first layer may include aluminum. The first layer may not include any alloy.

The second layer may have a thickness in a range of about 50 Å to about 300 Å.

The first layer may have a thickness in a range of about 500 Å to about 2000 Å.

The first pad electrode may further include a third layer located under the first layer. The third layer and the first layer may include a same material.

The metal layer may have a multi-layer structure including a fourth layer and a fifth layer disposed on the fourth layer. The fourth layer may include a material having an electrical conductivity higher than an electrical conductivity of the fifth layer. The fifth layer of the metal layer may be in direct contact with the third layer of the first pad electrode.

The metal layer may include a multi-layer structure including a fourth layer and a sixth layer disposed under the fourth layer. The fourth layer may include a material having an electrical conductivity higher than an electrical conductivity of the sixth layer. The fourth layer of the metal layer may be in direct contact with the third layer of the first pad electrode.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device in accordance with embodiments of the disclosure.

FIGS. 2A, 2B, and 2C are schematic circuit diagrams illustrating embodiments of a sub-pixel included in the display device shown in FIG. 1.

FIGS. 3A and 3B are schematic sectional views illustrating embodiments of the sub-pixel included in the display device shown in FIG. 1.

FIG. 4 is a schematic plan view illustrating an embodiment of a pixel included in the display device shown in FIG. 1.

FIG. 5 is a schematic plan view illustrating an embodiment of a pad included in the display device shown in FIG. 1.

FIG. 6 is a schematic sectional view illustrating an embodiment of the pad taken along line II-II′ shown in FIG. 5.

FIG. 7 is a schematic sectional view illustrating an embodiment of a first pad electrode shown in FIG. 6.

FIG. 8 is a schematic sectional view illustrating an embodiment of the pad shown in FIG. 6.

FIG. 9 is a schematic view illustrating a reflexibility of the first pad electrode shown in FIG. 6.

FIG. 10 is a schematic view illustrating a contact resistance of the first pad electrode shown in FIG. 6.

FIGS. 11A and 11B are schematic sectional views illustrating other embodiments of the pad shown in FIG. 6.

FIGS. 12A, 12B, and 12C are schematic sectional views illustrating other embodiments of the pad shown in FIG. 6.

FIGS. 13A and 13B are schematic sectional views illustrating an embodiment of the pixel included in the display device shown in FIG. 1.

FIG. 14 is a schematic view illustrating a light emitting element in accordance with an embodiment of the disclosure.

### DETAILED DESCRIPTION OF THE EMBODIMENTS

Example embodiments will now be described more fully hereinafter with reference to the accompanying drawings; however, the disclosure be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

As used herein, the singular forms are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

Each embodiment disclosed below may be independently embodied or be combined with at least another embodiment prior to being embodied.

In the following embodiments and the attached drawings, elements not directly related to the disclosure may be omitted from depiction, and dimensional relationships among individual elements in the attached drawings may be illustrated only for ease of understanding and not necessarily to limit the actual scale.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be further understood that the terms “comprise,” “include,” “have,” and the like, when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined or implied, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

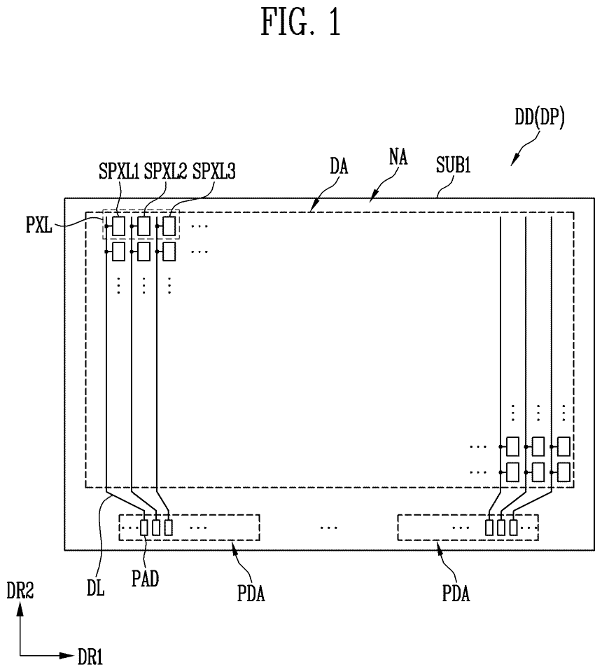

FIG. 1 is a schematic plan view illustrating a display device in accordance with embodiments of the disclosure. In FIG. 1, a display panel DP provided in the display device DD is illustrated.

In FIG. 1, a structure of the display panel DP will be briefly illustrated based on a display area DA. However, in some embodiments, at least one driving circuit (e.g., at least one of a scan driver and a data driver), lines, and/or pads, which are not shown in the drawing, may be further disposed in the display panel DP.

The disclosure may be applied as long as the display device DD is an electronic device in which a display surface is applied to at least one surface thereof, such as a smartphone, a television, a tablet personal computer (PC), a mobile phone, a video phone, an electronic book reader, a desktop PC, a laptop PC, a netbook computer, a workstation, a server, a personal digital assistant (PDA), a portable multimedia player (PMP), an MP3 player, a medical device, a camera, or a wearable device.

Referring to FIG. 1, the display panel DP may include a first substrate SUB1 (or base layer) and pixels PXL provided on the first substrate SUB1.

The display panel DP may have various shapes. In an example, the display panel DP may be provided in a rectangular plate shape, but the disclosure is not limited thereto. For example, the display panel DP may have a shape such as a circular shape or an elliptical shape. The display panel DP may include an angular corner and/or a curved corner. For convenience, a case where the display panel DP has a rectangular plate shape is illustrated in FIG. 1. In FIG. 1, an extending direction (e.g., a lateral direction) of long sides of the display panel DP is indicated as a first direction DR1, and an extending direction (e.g., a longitudinal direction) of short sides of the display panel DP is indicated as a second direction DR2.

The first substrate SUB1 may constitute a base member of the display panel DP, and may be a rigid or flexible substrate or film. In an example, the first substrate SUB1 may be configured as a rigid substrate made of glass or tempered glass, a flexible substrate (or thin film) made of plastic or metal, or at least one insulating layer. The material and/or property of the first substrate SUB1 is not particularly limited.

The first substrate SUB1 (and the display panel DP) may include a display area DA for displaying an image and a non-display area NA except the display area DA. The display area DA may constitute a screen on which the image is displayed, and the non-display area NA may be another area except the display area DA. The non-display area NA may be located at one or more sides of the display area DA. For example, the non-display area NA may surround the display area DA, but the disclosure is not limited thereto.

The pixels PXL may be disposed in the display area DA on the first substrate SUB1. The non-display area NA may be disposed at the periphery of the display area DA. Various lines, pads, and/or a built-in circuit, which are connected to the pixels PXL of the display area DA, may be disposed in the non-display area NA. The non-display area NA may include a pad area PDA, and pads PAD may be disposed in the pad area PDA. For example, the pads PAD may be connected to a driving circuit, such as a source driver or a timing controller, which is mounted on a flexible circuit board. In case that the display panel DP is connected to multiple source drivers, the pad area PDA may correspond to each source driver.

The pixel PXL may be connected to the pad PAD through a data line DL, and receive a data signal from the source driver. In case that a built-in circuit (e.g., a gate driver) is provided in the display panel DP, the built-in circuit may be connected to the pad PAD. Although a case where the pads PAD (or the pad area PDA) is disposed at a lower side of the display panel DP is illustrated in FIG. 1, the disclosure is not limited thereto. For example, the pads PAD may be respectively disposed at upper and lower sides of the display panel DP.

In the embodiments of the disclosure, the term “connection (or access)” may inclusively mean physical and/or electrical connection (or access). This may inclusively mean direct or indirect connection (or access) and integral or non-integral connection (or access).

The pixel PXL may include sub-pixels SPXL1 to SPXL3. For example, the pixel PXL may include a first sub-pixel SPXL1, a second sub-pixel SPXL2, and a third sub-pixel SPXL3.

Each of the sub-pixels SPXL1 to SPXL3 may emit light of a color (e.g., a predetermined or selected color). In some embodiments, the sub-pixels SPXL1 to SPXL3 may emit lights of different colors. In an example, the first sub-pixel SPXL1 may emit light of a first color, the second sub-pixel SPXL2 may emit light of a second color, and the third sub-pixel SPXL3 may emit light of a third color. For example, the first sub-pixel SPXL1 may be a red pixel emitting light of red, the second sub-pixel SPXL2 may be a green pixel emitting light of green, and the third sub-pixel SPXL3 may be a blue pixel emitting light of blue. However, the disclosure is not limited thereto.

In an embodiment, the first sub-pixel SPXL1, the second sub-pixel SPXL2, and the third sub-pixel SPXL3 may have, as light sources, a light emitting element of the first color, a light emitting element of the second color, and a light emitting element of the third color, to emit lights of the first color, the second color, and the third color, respectively. In another embodiment, the first sub-pixel SPXL1, the second sub-pixel SPXL2, and the third sub-pixel SPXL3 may have light emitting elements emitting light of the same color and include color conversion layers and/or color filters of different colors, which are disposed above the respective light emitting elements, to respectively emit lights of the first color, the second color, and the third color. However, the color, kind, and/or number of sub-pixels SPXL1 to SPXL3 constituting each pixel PXL are not particularly limited. For example, the color of light emitted by each pixel PXL may be variously changed.

The sub-pixels SPXL1 to SPXL3 may be regularly arranged according to a stripe structure, a PENTILE™ structure, or the like. For example, the first, second, and third sub-pixels SPXL1, SPXL2, and SPXL3 may be sequentially and repeatedly disposed along a first direction DR1. The first, second, and third sub-pixels SPXL1, SPXL2, and SPXL3 may be repeatedly disposed along a second direction DR2. At least one first sub-pixel SPXL1, at least one second sub-pixel SPXL2, and at least one third sub-pixel SPXL3, which are disposed adjacent to each other, may constitute one pixel PXL capable of emitting lights of various colors. However, the arrangement structure of the sub-pixels SPXL1 to SPXL3 is not limited thereto, and the sub-pixels SPXL1 to SPXL3 may be arranged in the display area DA in various structures and/or various manners.

In an embodiment, each of the sub-pixels SPXL1 to SPXL3 may be configured as an active pixel. For example, each of the sub-pixels SPXL1 to SPXL3 may include at least one light source (e.g., at least one light emitting element) driven by a predetermined or selected control signal (e.g., a scan signal and a data signal) and/or a predetermined or selected power source (e.g., a first power source and a second power source). However, the kind, structure, and/or driving method of the sub-pixels SPXL1 to SPXL3, which can be applied to the display device, are not particularly limited.

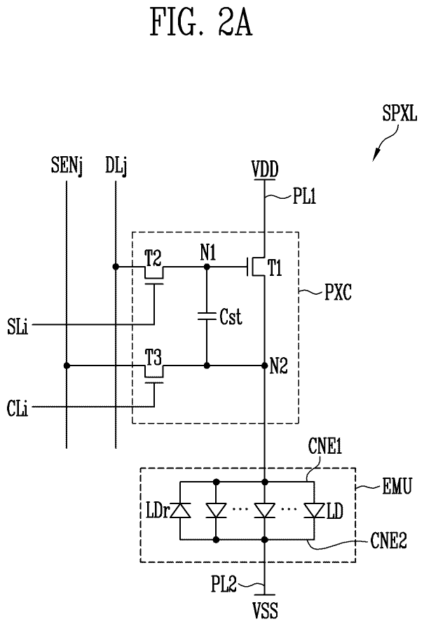

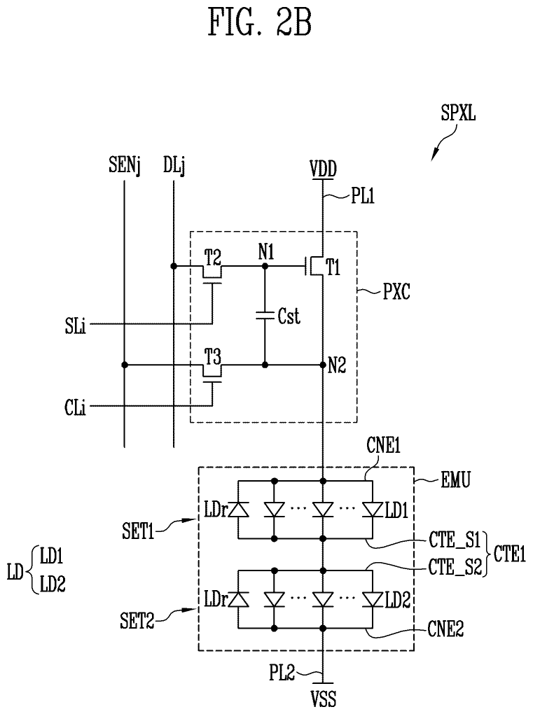

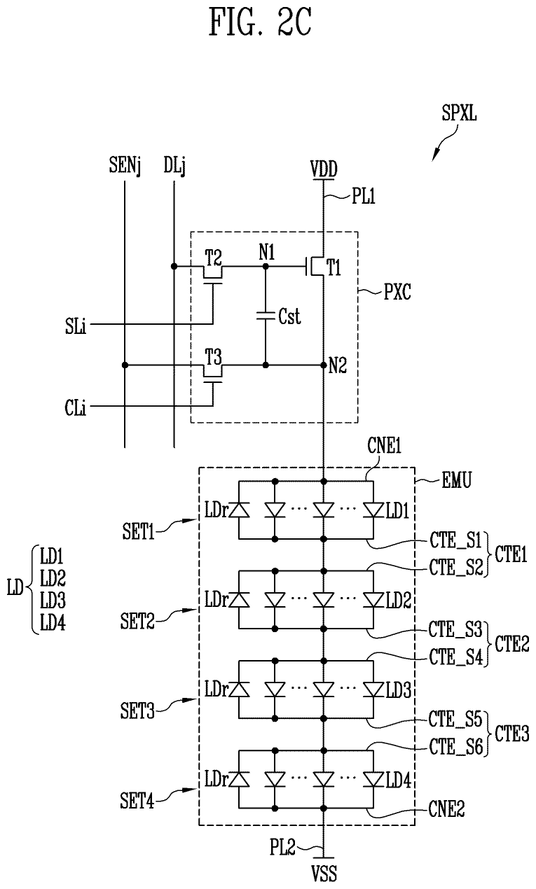

FIGS. 2A, 2B, and 2C are schematic circuit diagrams illustrating embodiments of the sub-pixel included in the display device shown in FIG. 1.

For example, FIGS. 2A, 2B, and 2C illustrate embodiments of an electrical connection relationship of components included in each of sub-pixels SPXL1 to SPXL3 applicable to an active matrix type display device. However, the connection relationship of the components of each of the sub-pixels SPXL1 to SPXL3 is not limited thereto. In the following embodiment, in case that a first sub-pixel SPXL1, a second sub-pixel SPXL2, and a third sub-pixel SPXL3 are inclusively designated, each of the first, second, and third sub-pixels SPXL1, SPXL2, and SPXL3 or the first, second, and third sub-pixels SPXL1, SPXL2, and SPXL3 will be referred to as a “sub-pixel SPXL” or “sub-pixels SPXL.”

Referring to FIGS. 1, 2A, 2B, and 2C, the sub-pixel SPXL may include a light emitting unit EMU (or light emitting part) which generates light with a luminance corresponding to a data signal. The sub-pixel SPXL may selectively further include a pixel circuit PXC for driving the light emitting unit EMU.

In some embodiments, the light emitting unit EMU may include multiple light emitting elements LD connected in parallel between a first power line PL1 and a second power line PL2. The first power line PL1 may be connected to a first driving power source VDD such that a voltage of the first driving power source VDD is applied thereto, and the second power line PL2 may be connected to a second driving power source VSS such that a voltage of the second driving power source VSS is applied thereto.

For example, the light emitting unit EMU may include a first pixel electrode CNE1 (or first electrode) connected to the first driving power source VDD via the pixel circuit PXC and the first power line PL1, a second pixel electrode CNE2 (or second electrode) connected to the second driving power source VSS through the second power line PL2, and multiple light emitting elements LD connected in parallel in the same direction between the first pixel electrode CNE1 and the second pixel electrode CNE2. In an embodiment, the first pixel electrode CNE1 may be an anode (or anode electrode), and the second pixel electrode CNE2 may be a cathode (or cathode electrode).

Each of the light emitting elements LD included in the light emitting unit EMU may include a first end portion connected to the first driving power source VDD through the first pixel electrode CNE1 and a second end portion connected to the second driving power source VSS through the second pixel electrode CNE2. The first driving power source VDD and the second driving power source VSS may have different potentials. In an example, the first driving power source VDD may be set as a high-potential power source, and the second driving power source VSS may be set as a low-potential power source. A potential difference between the first and second driving power sources VDD and VSS may be set equal to or higher than a threshold voltage of the light emitting elements LD during an emission period of each sub-pixel SPXL.

As described above, the light emitting elements LD connected in parallel in the same direction (e.g., a forward direction) between the first pixel electrode CNE1 and the second pixel electrode CNE2, to which voltages having difference potentials are supplied, may form respective effective light sources.

Each of the light emitting elements LD of the light emitting unit EMU may emit light with a luminance corresponding to a driving current supplied through a corresponding pixel circuit PXC. For example, the pixel circuit PXC may supply, to the light emitting unit EMU, a driving current corresponding to a grayscale value of corresponding frame data during each frame period. The driving current supplied to the light emitting unit EMU may be divided to flow through each of the light emitting elements LD. Accordingly, the light emitting unit EMU can emit light with a luminance corresponding to the driving current while each light emitting element LD is emitting light with a luminance corresponding to a current flowing therethrough.

Although an embodiment in which both the end portions of the light emitting elements LD are connected in the same direction between the first and second driving power sources VDD and VSS has been described, the disclosure is not limited thereto. In some embodiments, the light emitting unit EMU may further include at least one ineffective light source, e.g., a reverse light emitting element LDr, in addition to the light emitting elements LD forming the respective effective light sources. The reverse light emitting element LDr is connected in parallel together with the light emitting elements LD forming the effective light sources between the first and second pixel electrodes CNE1 and CNE2, and may be connected between the first and second pixel electrodes CNE1 and CNE2 in a direction opposite to that in which the light emitting elements LD are connected. Although a predetermined or selected driving voltage (e.g., a forward driving voltage) may be applied between the first and second pixel electrodes CNE1 and CNE2, the reverse light emitting element LDr may maintain an inactivated state, and accordingly, no current may substantially flow through the reverse light emitting element LDr.

The pixel circuit PXC may be connected to a scan line SLi (or first gate line) and a data line DLj of the sub-pixel SPXL. The pixel circuit PXC may be connected to a control line CLi (or second gate line) and a sensing line SENj (or readout line) of the sub-pixel SPXL. In an example, in case that the sub-pixel SPXL is disposed on an ith row and a jth column of the display area DA, the pixel circuit PXC of the sub-pixel SPXL may be connected an ith scan line SLi, a jth data line DLj, an ith control line CLi, and a jth sensing line SENj of the display area DA. In some embodiments, the control line CLi may be connected to the scan line SLi or be the scan line SLi.

The pixel circuit PXC may include transistors T1 to T3 and a storage capacitor Cst (or capacitor).

A first transistor T1 may be a driving transistor for controlling a driving current applied to the light emitting unit EMU, and may be connected between the first driving power source VDD and the light emitting unit EMU. Specifically, a first terminal (or a first transistor electrode) of the first transistor T1 may be electrically connected to the first driving power source VDD through the first power line PL1, a second terminal (or second transistor electrode) of the first transistor T1 may be electrically connected to a second node N2, and a gate electrode of the first transistor T1 may be electrically connected to a first node N1. The first transistor T1 may control an amount of driving current applied to the light emitting unit EMU through the second node N2 from the first driving power source VDD according to a voltage applied to the first node N1. In an embodiment, the first terminal of the first transistor T1 may be a drain electrode, and the second terminal of the first transistor T1 may be a source electrode. However, the disclosure is not limited thereto. In some embodiments, the first terminal may be the source electrode, and the second terminal may be the drain electrode.

A second transistor T2 may be a switching transistor which selects a sub-pixel SPXL in response to a scan signal and activates the sub-pixel SPXL, and may be connected between the data line DLj and the first node N1. A first terminal of the second transistor T2 may be connected to the data line DLj, a second terminal of the second transistor T2 may be connected to the first node N1, and a gate electrode of the second transistor T2 may be connected to the scan line SLi. The first terminal and the second terminal of the second transistor T2 may be different terminals. For example, in case that the first terminal is a drain electrode, the second terminal may be a source electrode.

The second transistor T2 may be turned on in case that a scan signal having a gate-on voltage (e.g., a high level voltage) is supplied from the scan line SLi, to electrically connect the data line DLj and the first node N1 to each other. The first node N1 may be a point at which the second terminal of the second transistor T2 and the gate electrode of the first transistor T1 are connected to each other, and the second transistor T2 may transfer a data signal to the gate electrode of the first transistor T1.

A first terminal of a third transistor T3 may be connected to the sensing line SENj, a second terminal of the third transistor T3 may be connected to the second terminal of the first transistor T1, and a gate electrode of the third transistor T3 may be connected to the control line CLi. An initialization power source may be applied to the sensing line SENj. The third transistor T3 may be an initialization transistor capable of initializing the second node N2, and may be turned on in case that a sensing control signal is supplied from the control line CLi, to transfer a voltage of the initialization power source to the second node N2. Accordingly, a second storage electrode of the storage capacitor Cst, which is electrically connected to the second node N2, may be initialized. In some embodiments, the third transistor T3 may connect the first transistor T1 to the sensing line SENj, so that a sensing signal is acquired through the sensing line SENj. Thus, a characteristic of the sub-pixel SPXL, including a threshold voltage of the first transistor T1, and the like, can be detected by using the sensing signal. Information on the characteristic of the sub-pixel SPXL may be used to convert image data such that a characteristic deviation between sub-pixels SPXL can be compensated.

The storage capacitor Cst may be formed between the first node N1 and the second node N2, or be electrically connected between the first node N1 and the second node N2. The storage capacitor Cst may charge a data voltage corresponding to the data signal supplied to the first node N1 during a frame period. Accordingly, the storage capacitor Cst may store a voltage corresponding to the difference between a voltage of the gate electrode of the first transistor T1 and a voltage of the second node N2.

The light emitting unit EMU may be configured to include at least one serial stage (or stage) including multiple light emitting elements LD electrically connected in parallel to each other.

In an embodiment, the light emitting unit EMU may be configured in a series/parallel hybrid structure. In an example, as shown in FIG. 2B, the light emitting unit EMU may be configured to include a first serial stage SET1 and a second serial stage SET2. In another example, as shown in FIG. 2C, the light emitting unit EMU may be configured to include a first serial stage SET1, a second serial stage SET2, a third serial stage SET3, and a fourth serial stage SET4. The number of serial stages included in the light emitting unit EMU may be variously changed. For example, the light emitting unit EMU may include three, or five or more serial stages.

Referring to FIG. 2B, the light emitting unit EMU may include a first serial stage SET1 and a second serial stage SET2, which are sequentially connected between the first driving power source VDD and the second driving power source VSS. Each of the first serial stage SET1 and the second serial stage SET2 may include two electrodes CNE1 and CTE_S1 or CTE_S2 and CNE2 constituting an electrode pair of the corresponding serial stage and multiple light emitting elements LD connected in parallel in the same direction between the two electrodes CNE1 and CTE_S1 or CTE_S2 and CNE2.

The first serial stage SET1 (or first stage) may include first pixel electrode CNE1 (or second pixel electrode) and a first sub-intermediate electrode CTE_S1, and include at least one first light emitting element LD1 connected between the first pixel electrode CNE1 and the first sub-intermediate electrode CTE_S1. The first serial stage SET1 may further include a reverse light emitting element LDr connected in the opposite direction of the direction in which the first light emitting element LD1 is connected between the first pixel electrode CNE1 and the first sub-intermediate electrode CTE_S1.

The second serial stage SET2 (or second stage) may include a second sub-intermediate electrode CTE_S2 and a second pixel electrode CNE2 (or first pixel electrode), and include at least one second light emitting element LD2 connected between the second sub-intermediate electrode CTE_S2 and the second pixel electrode CNE2. The second serial stage SET2 may further include a reverse light emitting element LDr connected in the opposite direction of the direction in which the second light emitting element LD2 is connected between the second sub-intermediate electrode CTE_S2 and the second pixel electrode CNE2.

The first sub-intermediate electrode CTE_S1 of the first serial stage SET1 and the second sub-intermediate electrode CTE_S2 of the second serial stage SET2 may be integrally provided to be connected to each other. In an example, the first sub-intermediate electrode CTE_S1 and the second sub-intermediate electrode CTE_S2 may constitute a first intermediate electrode CTE1 for electrically connecting the first serial stage SET1 and the second serial stage SET2, which are consecutive. In case that the first sub-intermediate electrode CTE_S1 and the second sub-intermediate electrode CTE_S2 are integrally provided, the first sub-intermediate electrode CTE_S1 and the second sub-intermediate electrode CTE_S2 may be different areas of the first intermediate electrode CTE1. The terms “pixel electrode” and “intermediate electrode” are merely expressions for distinguishing electrodes from each other, and corresponding components (i.e., electrodes) are not limited by the terms.

Referring to FIG. 2C, the light emitting unit EMU may include a first serial stage SET1, a second serial stage SET2, a third serial stage SET3, and a fourth serial stage SET4, which are sequentially connected between the first driving power source VDD and the second driving power source VSS.

The first serial stage SET1 shown in FIG. 2C may be substantially identical to the first serial stage SET1 shown in FIG. 2B.

The second serial stage SET2 may include at least one second light emitting element LD2 connected between a second sub-intermediate electrode CTE_S2 and a third sub-intermediate electrode CTE_S3. The third serial stage SET3 may include at least one third light emitting element LD3 connected between a fourth sub-intermediate electrode CTE_S4 and a fifth sub-intermediate electrode CTE_S5. The fourth serial stage SET may include at least one fourth light emitting element LD4 connected between a sixth sub-intermediate electrode CTE_S6 and a second pixel electrode CNE2. The third sub-intermediate electrode CTE_S3 and the fourth sub-intermediate electrode CTE_S4 may be integrally provided to be connected to each other, and may constitute a second intermediate electrode CTE2. The fifth sub-intermediate electrode CTE_S5 and the sixth sub-intermediate electrode CTE_S6 may be integrally provided to be connected to each other, and may constitute a third intermediate electrode CTE3.

As described above, the light emitting unit EMU of the sub-pixel SPXL, which includes serial stages SET1 to SET4 (or light emitting elements LD) connected in a series/parallel hybrid structure, can readily control driving current/voltage conditions to be suitable for specifications of a product to which the light emitting unit EMU is applied.

In particular, the light emitting unit EMU of the sub-pixel SPXL, which includes the serial stages SET1 to SET4, can decrease a driving current, as compared with a light emitting unit having a structure in which light emitting elements LD are connected only in parallel. In other words, the light emitting unit EMU of the sub-pixel SPXL, which includes the serial stages SET1 to SET4, can emit light with a higher luminance with respect to the same driving current.

The light emitting unit EMU of the sub-pixel SPXL, which includes the serial stages SET1 to SET4, can decrease a driving voltage applied to both ends of the light emitting unit EMU, as compared with a light emitting unit having a structure in which the same number of light emitting elements LD are connected only in series.

Although a case where the transistors T1 to T3 included in the pixel circuit PXC are all n-type transistors is illustrated in FIGS. 2A, 2B, and 2C, the disclosure is not necessarily limited thereto. For example, at least one of the transistors T1 to T3 may be changed to a p-type transistor.

The structure and driving method of the sub-pixel SPXL may be variously changed. For example, the pixel circuit PXC may be configured as a pixel circuit having various structures and/or various driving methods, in addition to the embodiment shown in FIGS. 2A, 2B, and 2C.

In an example, the pixel circuit PXC may not include the third transistor T3. The pixel circuit PXC may further include other circuit elements such as a compensation transistor for compensating for the threshold voltage of the first transistor T1, or the like, an initialization transistor for initializing a voltage of the first node N1 and/or the first pixel electrode CNE1, an emission control transistor for controlling a period in which a driving current is supplied to the light emitting unit EMU, and/or a boosting capacitor for boosting the voltage of the first node N1.

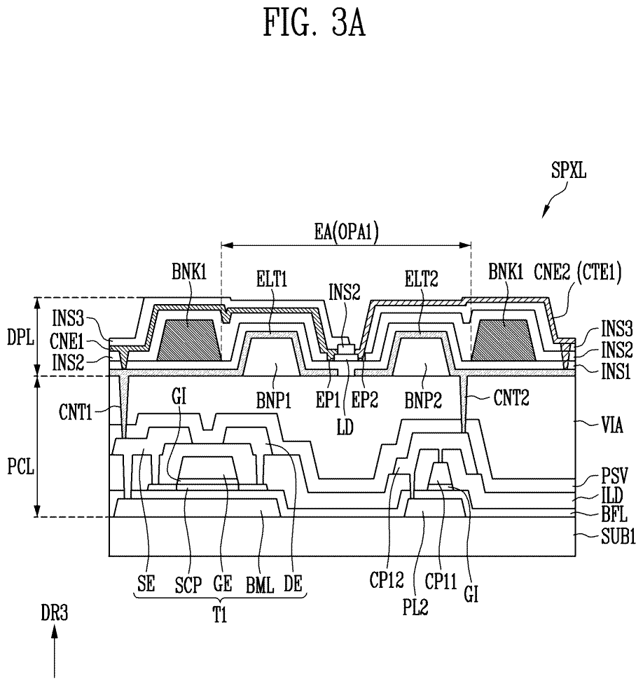

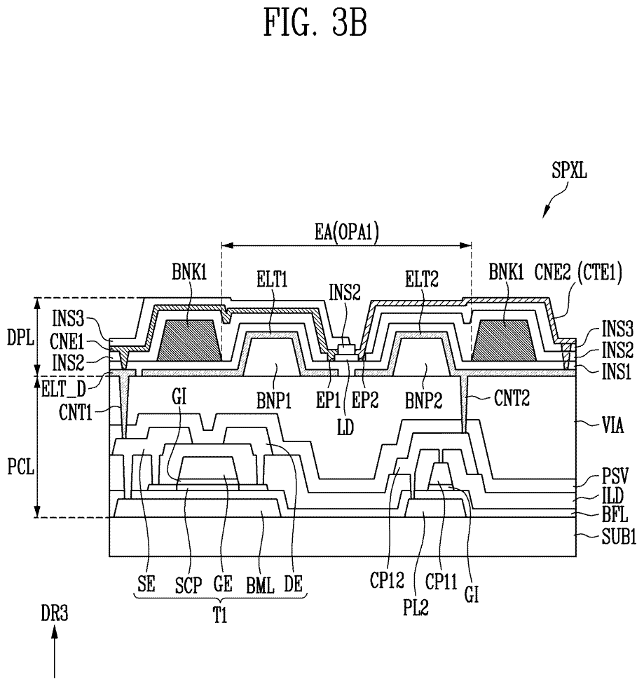

FIGS. 3A and 3B are schematic sectional views illustrating embodiments of the sub-pixel included in the display device shown in FIG. 1. In FIGS. 3A and 3B, a first transistor T1 (see FIG. 2A) and a second power line PL2 are illustrated as an example of circuit elements which may be disposed in a pixel circuit layer PCL.

First, referring to FIGS. 1 and 3A, the sub-pixel SPXL (or the display device) may include a pixel circuit layer PCL and a display element layer DPL, which are disposed on a first substrate SUB1.

The pixel circuit layer PCL may include a first transistor T1, a second power line PL2, and multiple insulating layers BFL, GI, ILD, PSV, and VIA. The first transistor T1 may include a bottom metal layer BML, a semiconductor pattern SCP, a gate electrode GE, a source electrode SE (second transistor electrode, or second terminal), and a drain electrode DE (first transistor electrode, or first terminal).

A first conductive layer may be located between the first substrate SUB1 and a buffer layer BFL. The first conductive layer may include a conductive material. The conductive material may include at least one metal or among various metallic materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and/or the like, or alloys thereof. The first conductive layer may be configured as a single layer, a double layer, or a multi-layer.

The first conductive layer may include the bottom metal layer BML and the second power line PL2. The bottom metal layer BML and the gate electrode GE of the first transistor T1 may overlap each other with the buffer layer BFL interposed therebetween. The bottom metal layer BML may be disposed under the semiconductor pattern SCP of the first transistor T1. The bottom metal layer BML may serve as a light blocking pattern, thereby stabilizing an operational characteristic of the first transistor T1. The bottom metal layer BML may be physically and/or electrically connected to the source electrode SE of the first transistor T1 which will be described later through a contact hole of insulating layers. Accordingly, a threshold voltage of the first transistor T1 can be moved in a negative direction or a positive direction.

In some embodiments, the first transistor T1 may not include the bottom metal layer BML. The buffer layer BFL may be located directly on the first substrate SUB1.

The buffer layer BFL (or first insulating layer) may be located on the first substrate SUB1, and cover the first conductive layer.

The buffer layer BFL may prevent an impurity from being diffused into the pixel circuit layer PCL. The buffer layer BFL may include an inorganic material. For example, the inorganic material may include at least one of silicon nitride (SiNₓ), silicon oxide (SiOₓ), silicon oxynitride (SiOₓN_{y}), and metal oxide such as aluminum nitride (AlNₓ). The buffer layer BFL may be omitted according to a material of the substrate SUB, a process condition, and the like.

The semiconductor pattern SCP may be located on the buffer layer BFL. The semiconductor pattern SCP may include a first region (e.g., a source region) connected to the source electrode SE, a second region (e.g., a drain region) connected to the drain electrode DE, and a channel region between the first and second regions. The channel region may overlap the gate electrode GE of the first transistor T1. The semiconductor pattern SCP may be a semiconductor pattern made of poly-silicon, amorphous silicon, an oxide semiconductor, and/or the like.

A gate insulating layer GI (or second insulating layer) may be disposed over the semiconductor pattern SCP. The gate insulating layer GI may be partially disposed on only the semiconductor pattern SCP, or be entirely disposed on the first substrate SUB1. The gate insulating layer GI may include an inorganic material. However, the disclosure is not limited thereto, and the gate insulating layer GI may include an organic material. For example, the organic material may include at least one of acrylic resin, epoxy resin, phenolic resin, polyamide resin, polyimide resin, unsaturated polyester resin, poly-phenylene ether resin, poly-phenylene sulfide resin, and benzocyclobutene resin.

A second conductive layer may be disposed on the gate insulating layer GI. The second conductive layer may include a conductive material, similar to the first conductive layer. The second conductive layer may include the gate electrode GE and an eleventh connection pattern CP11.

The gate electrode GE may be disposed on the gate insulating layer GI to overlap the channel region of the semiconductor pattern SCP. The eleventh connection pattern CP11 may overlap the second power line PL2.

An interlayer insulating layer ILD (first interlayer insulating layer, or third insulating layer) may cover the second conductive layer, and be entirely disposed on the first substrate SUB1. The interlayer insulating layer ILD may include an inorganic material, similar to the gate insulating layer GI. The interlayer insulating layer ILD may include an organic material.

A third conductive layer may be disposed on the interlayer insulating layer ILD. The third conductive layer may include a conductive material, similar to the first conductive layer. The third conductive layer may include the source electrode SE, the drain electrode DE, and a twelfth connection pattern CP12.

The source electrode SE may be in contact with or connected to the first region of the semiconductor pattern SCP through a contact hole penetrating the interlayer insulating layer ILD, and be in contact with or connected to the bottom metal layer BML through a contact hole penetrating the interlayer insulating layer ILD and the buffer layer BFL. The drain electrode DE may be in contact with or connected to the second region of the semiconductor pattern SCP through a contact hole penetrating the interlayer insulating layer ILD. Similar to the source electrode SE, the twelfth connection pattern CP12 may be in contact with or connected to the second power line PL2 and the eleventh connection pattern CP11. The eleventh connection pattern CP11 and the twelfth connection pattern CP12 may be connected to the second power line PL2, to reduce resistance of the second power line PL2.

A protective layer PSV (or second interlayer insulating layer) may be entirely disposed on the first substrate SUB1 to cover the third conductive layer. The protective layer PSV may include an inorganic material. The protective layer PSV may be provided as a single layer, and be provided as a multi-layer including two or more layers. In some embodiments, the protective layer PSV may be omitted.

A via layer VIA (passivation layer, or insulating layer) may be disposed on the protective layer PSV. The via layer VIA may be entirely disposed on the first substrate SUB1. The via layer VIA may include an organic material. A flat surface may be provided on the top of the via layer VIA.

The display element layer DPL may be located on the via layer VIA.

The display element layer DPL may include first and second bank patterns BNP1 and BNP2, first and second electrodes ELT1 and ELT2 (alignment electrodes, or reflective electrodes), a first bank BNK1, a light emitting element LD, first and second pixel electrodes CNE1 and CNE2 (or contact electrodes), and multiple insulating layers INS1 to INS3.

The first and second bank patterns BNP1 and BNP2 may be disposed on the via layer VIA.

Each of the first and second bank patterns BNP1 and BNP2 may have a section of a trapezoidal shape, of which width becomes narrower as approaching the top thereof along a third direction DR3 from a surface (e.g., an upper surface) of the via layer VIA. In some embodiments, each of the first and second bank patterns BNP1 and BNP2 may include a curved surface having a section of a semi-elliptical shape, a semicircular shape (or hemisphere shape), or the like, of which width becomes narrower as approaching the top thereof along the third direction DR3 from the surface of the via layer VIA. When viewed on a section, the shape of each of the first and second bank patterns BNP1 and BNP2 is not limited to the above-described embodiments, and may be variously changed within a range in which the efficiency of light emitted from each of the light emitting elements LD can be improved.

The first and second bank patterns BNP1 and BNP2 may include an inorganic material and/or an organic material, and be configured as a single layer or a multi-layer. In some embodiments, the first and second bank patterns BNP1 and BNP2 may be omitted. For example, a structure corresponding to the first and second bank patterns BNP1 and BNP2 may be formed in the via layer VIA.

The first and second electrodes ELT1 and ELT2 may be disposed on the via layer VIA and the first and second bank patterns BNP1 and BNP2.

The first electrode ELT1 may be disposed over the first bank pattern BNP1, the second electrode ELT2 may be disposed over the second bank pattern BNP2. When viewed on a section, the first and second electrodes ELT1 and ELT2 may have surface profiles respectively corresponding to the shapes of the first and second bank patterns BNP1 and BNP2.

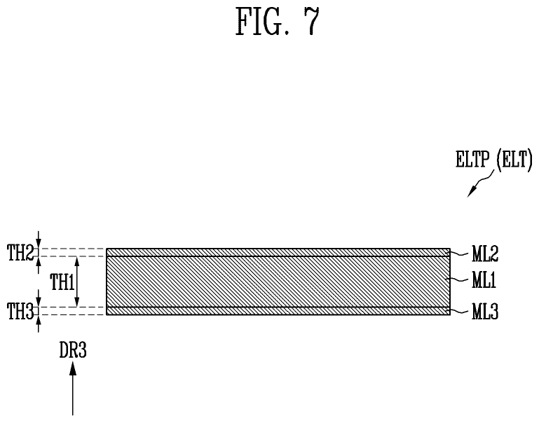

Each of the first and second electrodes ELT1 and ELT2 may include a conductive material having a constant reflexibility to allow light emitted from the light emitting element LD to advance in an image display direction of the display device (e.g., the third direction DR3). Each of the first and second electrodes ELT1 and ELT2 may be configured as a single layer or a multi-layer. In embodiments, the first and second electrodes ELT1 and ELT2 may form a double-layer structure or a multi-layer structure so as to reduce line resistance (or contact resistance), and include at least one material selected from copper (Cu), molybdenum (Mo), tungsten (W), aluminum neodymium (AlNd), titanium (Ti), aluminum (Al), silver (Ag), and alloys thereof. The structure of the first and second electrodes ELT1 and ELT2 will be described later with reference to FIG. 7.

The first electrode ELT1 may be in contact with or connected to the source electrode SE of the first transistor T1 through a first contact hole CNT1 penetrating the via layer VIA and the protective layer PSV. The second electrode ELT2 may be in contact with or connected to the twelfth connection pattern CP12 through a second contact hole CNT2 penetrating the via layer VIA and the protective layer PSV. The second electrode ELT2 may be electrically connected to the second power line PL2.

The first and second electrodes ELT1 and ELT2 may be used as alignment electrodes for aligning the light emitting element LD in a manufacturing process of the display device.

A first insulating layer INS1 may be disposed on the via layer VIA to cover at least a portion of the first and second electrodes ELT1 and ELT2. The first insulating layer INS1 may be located between the first electrode ELT1 and the second electrode ELT2, and prevent a short circuit between the first electrode ELT1 and the second electrode ELT2. The first insulating layer INS1 may include an inorganic material or an organic material.

The light emitting element LD may be disposed on the first insulating layer INS1. The light emitting element LD may be an inorganic light emitting diode. The light emitting element LD may be aligned between the first electrode ELT1 and the second electrode ELT2 such that a first end portion EP1 of the light emitting element LD faces the first electrode ELT1 and a second end portion EP2 of the light emitting element LD faces the second electrode ELT2.

The first end portion EP1 of the light emitting element LD may partially overlap the first electrode ELT1 in the third direction DR3, and the second end portion EP2 of the light emitting element LD may partially overlap the second electrode ELT2 in the third direction DR3. However, the disclosure is not limited thereto.

The first bank BNK1 may be disposed on the first insulating layer INS1. The first bank BNK1 may be a dam structure which prevents a solution including the light emitting element LD from being introduced into an adjacent sub-pixel SPXL or controls a certain amount of solution to be supplied to each sub-pixel SPXL. The first bank BNK1 may define an emission area EA. For example, the emission area EA may correspond to an opening OPAl of the first bank BNKL.

The first bank BNK1 may include an organic material. In some embodiments, the first bank BNK1 may include a light blocking material and/or a reflective material. The first bank BNK1 may prevent a light leakage defect in which light (or beam) is leaked between the sub-pixel SPXL and sub-pixel adjacent thereto. For example, the first bank BNK1 may include a color filter material or a black matrix material. In another example, a reflective material layer may be separately provided and/or formed over the first bank BNK1 so as to further improve the efficiency of light emitted to the outside from the sub-pixel SPXL.

A second insulating layer INS2 (or second insulating pattern) may be disposed on the light emitting element LD. The second insulating layer INS2 may be located on a portion of a top surface of the light emitting element LD such that the first end portion EP1 and the second end portion EP2 of the light emitting element LD are exposed to the outside. In some embodiments, the second insulating layer INS2 may be disposed even on the first insulating layer INS1 and the first bank BNK1.

The second insulating layer INS2 may include an inorganic material or an organic material according to a design condition of the display device including the light emitting element LD, and the like. After the light emitting element LD is completely aligned on the first insulating layer INS1, the second insulating layer INS2 is located on the light emitting element LD, so that the light emitting element LD can be prevented from being separated at the position at which the light emitting element LD is aligned. In case that an empty gap (or space) exists between the first insulating layer INS1 and the light emitting element LD before the second insulating layer INS2 is formed, the empty gap may be filled with the second insulating layer INS2 in a process of forming the second insulating layer INS2.

The first pixel electrode CNE1 may be disposed on the first electrode ELT1. The first pixel electrode CNE1 may be in direct contact with the first end portion EP1 of the light emitting element LD. The first pixel electrode CNE1 may be in contact with or connected to the first electrode ELT1 through a contact hole penetrating the second insulating layer INS2 and the first insulating layer INS1. The first pixel electrode CNE1 (and the first electrode ELT1) may electrically connect the first end portion EP1 of the light emitting element LD to the source electrode SE of the first transistor T1.

The first pixel electrode CNE1 and the second pixel electrode CNE2 may include a transparent conductive material such as indium tin oxide (ITO), indium zinc oxide (IZO), zinc oxide (ZnOₓ), and/or indium gallium zinc oxide (IGZO).

A third insulating layer INS3 may be located over the second insulating layer INS2 and the first pixel electrode CNE1 to cover the second insulating layer INS2 and the first pixel electrode CNE1. The third insulating layer INS3 may be located such that an edge of the third insulating layer INS3 is in contact with one end of the second insulating layer INS2. Therefore, the second end portion EP2 of the light emitting element LD may be exposed.

The third insulating layer INS3 may include an inorganic material or an organic material.

The second pixel electrode CNE2 (or a first intermediate electrode CTE1) may be disposed on the second electrode ELT2. The second pixel electrode CNE2 may be in direct contact with the second end portion EP2 of the light emitting element LD. In some embodiments, the second pixel electrode CNE2 may be in contact with or connected to the second electrode ELT2 through a contact hole penetrating the third insulating layer INS3, the second insulating layer INS2, and the first insulating layer INS1. The second pixel electrode CNE2 (and the second electrode ELT2) may electrically connect the second end portion EP2 of the light emitting element LD to the second power line PL2.

Although a case where the first pixel electrode CNE1 and the second pixel electrode CNE2 are located in different layers with the third insulating layer INS3 interposed therebetween has been described in FIG. 3A, the disclosure is not limited thereto. For example, the first pixel electrode CNE1 and the second pixel electrode CNE2 may be disposed on the same layer (e.g., the second insulating layer INS2) through the same process.

Although a case where the first pixel electrode CNE1 is connected to the source electrode SE of the first transistor T1 through the first electrode ELi has been illustrated in FIG. 3A, the disclosure is not limited thereto. For example, as shown in FIG. 3B, the sub-pixel SPXL (or the display device) may further include a bridge electrode ELT_D electrically separated from the first electrode ELT1, and the first pixel electrode CNE1 may be connected to the source electrode SE of the first transistor T1 through the bridge electrode ELT_D. Similarly, the second pixel electrode CNE2 is not directly connected to the twelfth connection pattern CP12 through the second electrode ELT2, but may be connected to the twelfth connection pattern CP12 through a bridge electrode electrically separated from the second electrode ELT2.

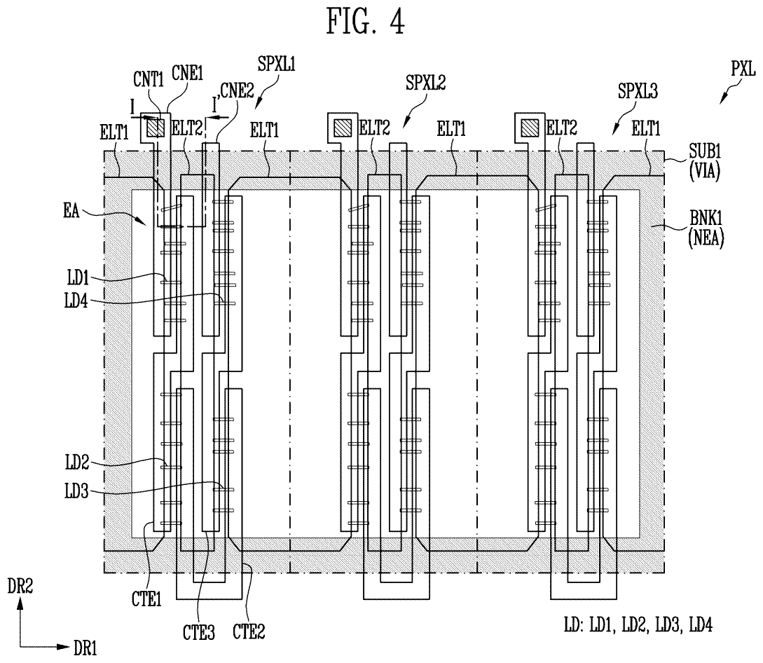

FIG. 4 is a schematic plan view illustrating an embodiment of the pixel included in the display device shown in FIG. 1. In FIG. 4, a pixel PXL is briefly illustrated based on a light emitting unit EMU (see FIG. 2C). A section taken along line I-I′ shown in FIG. 4 may correspond to FIG. 3.

Referring to FIGS. 1 and 4, a first sub-pixel SPXL1, a second sub-pixel SPXL2, and a third sub-pixel SPXL3 may have structures (or light emitting units EMU (see FIG. 2C)) substantially identical or similar to one another. Therefore, common components of the first sub-pixel SPXL1, the second sub-pixel SPXL2, and the third sub-pixel SPXL3 are described based on the first sub-pixel SPXL1, and overlapping descriptions will not be repeated.

The pixel PXL may be formed in a pixel area provided in a first substrate SUB1 (or a via layer VIA). The pixel area may include an emission area EA and a non-emission area NEA except the emission area EA. The non-emission area NEA may be an area surrounding the emission area EA, and the emission area EA may be defined by a first bank BNK1. However, the disclosure is not limited thereto.

The pixel PXL may include first and second electrodes ELT1 and ELT2, a light emitting element LD, first and second pixel electrodes CNE1 and CNE2, and intermediate electrodes CTE1 to CTE3, but the disclosure is not limited thereto.

Each of the first and second electrodes ELT1 and ELT2 may extend in the second direction DR2, and the first and second electrodes ELT1 and ELT2 may be spaced apart from each other in the first direction DR1. The first and second electrodes ELT1 and ELT2 may be repeatedly arranged along the first direction DR1.

The first and second electrodes ELT1 and ELT2 may be respectively separated from first and second electrodes ELT1 and ELT2 included in a pixel adjacent to the pixel PXL in the second direction DR2, but the disclosure is not limited thereto. For example, at least one of the first and second electrodes ELT1 and ELT2 of the pixel PXL may be connected to an electrode corresponding to the pixel adjacent to the pixel PXL in the second direction DR2.

The first and second electrodes ELT1 and ELT2 may be used as alignment electrodes by inputting a mixed liquor (e.g., an ink) including the light emitting element LD to the emission area EA and applying an alignment voltage. The first electrode ELT1 may become a first alignment electrode, and the second electrode ELT2 may become a second alignment electrode. The light emitting element LD may be aligned in a desired direction and/or at a desired position by an electric field formed between the first alignment electrode and the second alignment electrode.

The first and second electrodes ELT1 and ELT2 may have a bar shape extending along the second direction DR2 in plan view, but the disclosure is not limited thereto. The shape of the first and second electrodes ELT1 and ELT2 may be variously changed.

Light emitting elements LD may be disposed between the first and second electrodes ELT1 and ELT2 such that a length L direction (see FIG. 1) of each of the light emitting elements LD is substantially parallel to the first direction DR1. For example, in the first sub-pixel SPXL1, a first light emitting element LD1 may be disposed in an upper area of a first area (or first lane) between a first electrode ELT1 and a left second electrode ELT2, and a second light emitting element LD2 may be disposed in a lower area of the first area. A third light emitting element LD3 may be disposed in a lower area of a second area (or second lane) between a right second electrode ELT2 and the first electrode ELT1, and a fourth light emitting element LD4 may be disposed in an upper area of the second area.

The first pixel electrode CNE1 may be located to overlap a first end portion of the first light emitting element LD1 and the first electrode ELT1. The first pixel electrode CNE1 may be connected to the first end portion of the first light emitting element LD1. The first pixel electrode CNE1 may constitute an anode of the light emitting unit EMU (see FIG. 2C), and be connected to the first transistor T1 (see FIGS. 2C, 3A, and 3B) through a first contact hole CNT1 (and the first electrode ELT1). The first pixel electrode CNE1 may extend in the second direction DR2, corresponding to the first electrode ELT1.

A first intermediate electrode CTE1 may be located to overlap a second end portion of the first light emitting element LD1 and the second electrode ELT2. The first intermediate electrode CTE1 may be located to overlap a first end portion of the second light emitting element LD2 and the first electrode ELT1. To this end, a portion of the first intermediate electrode CTE1 may have a bent shape. The first intermediate electrode CTE1 may physically and/or electrically connect the second end portion of the first light emitting element LD1 and the first end portion of the second light emitting element LD2 to each other.

A second intermediate electrode CTE2 may be located to overlap a second end portion of the second light emitting element LD2 and the second electrode ELT2. The second intermediate electrode CTE2 may be located to overlap a first end portion of the third light emitting element LD3 and the first electrode ELT1. The second intermediate electrode CTE2 may have a shape bypassing a third intermediate electrode CTE3. The second intermediate electrode CTE2 may physically and/or electrically connect the second end portion of the second light emitting element LD2 and the first end portion of the third light emitting element LD3 to each other.

The third intermediate electrode CTE3 may be located to overlap a second end portion of the third light emitting element LD3 and the second electrode ELT2. The third intermediate electrode CTE3 may be located to overlap a first end portion of the fourth light emitting element LD4 and the first electrode ELT1. To this end, a portion of the third intermediate electrode CTE3 may have a bent shape. The third intermediate electrode CTE3 may physically and/or electrically connect the second end portion of the third light emitting element LD3 and the first end portion of the fourth light emitting element LD4 to each other.

The second pixel electrode CNE2 may be located to overlap a second end portion of the fourth light emitting element LD4 and the second electrode ELT2. The second pixel electrode CNE2 may be connected to the second end portion of the fourth light emitting element LD4. The second pixel electrode CNE2 may constitute a cathode of the light emitting unit EMU (see FIG. 2C), and be electrically connected to the second power line. The second pixel electrode CNE2 may extend in the second direction DR2, corresponding to the second electrode ELT2.

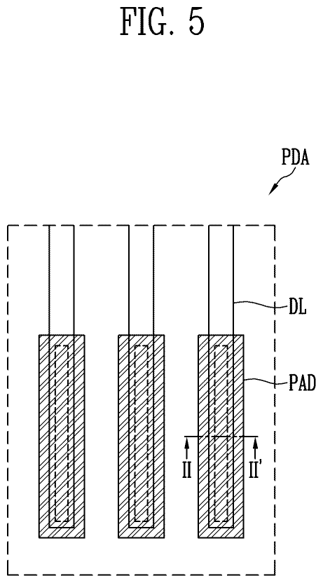

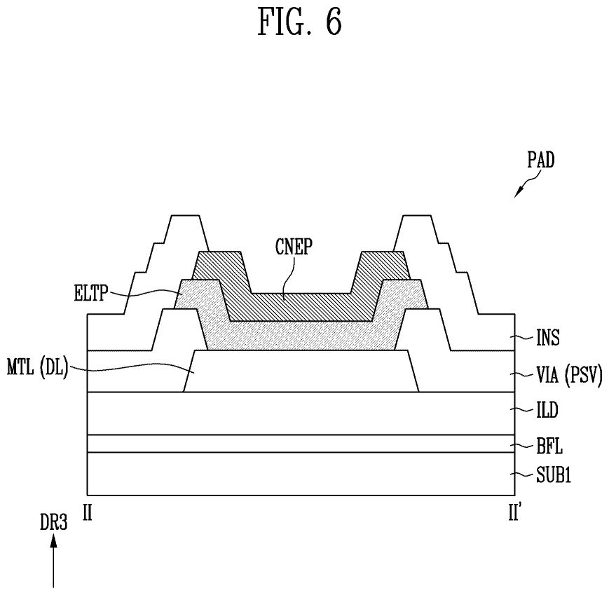

FIG. 5 is a schematic plan view illustrating an embodiment of the pad included in the display device shown in FIG. 1. A pad PAD connected to a data line DL is illustrated in FIG. 5. FIG. 6 is a schematic sectional view illustrating an embodiment of the pad taken along line II-II′ shown in FIG. 5.

Referring to FIGS. 1, 5, and 6, the pad PAD may be disposed in a pad area PDA, and be connected to a data line DL (or signal line).

A first substrate SUB1, a buffer layer BFL, an interlayer insulating layer ILD, and a via layer VIA (and a protective layer PSV) have been described with reference to FIG. 3A, and therefore, overlapping descriptions will not be repeated. An insulating layer INS may correspond to the third insulating layer INS3 described with reference to FIG. 3A, and therefore, overlapping descriptions will not be repeated.

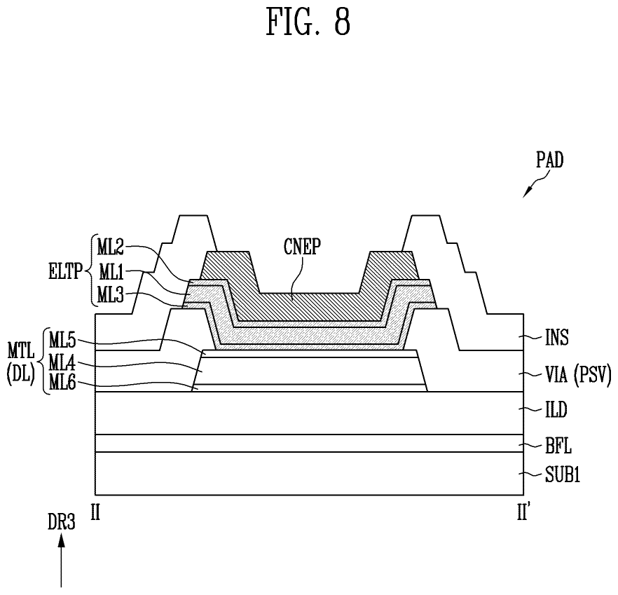

The data line DL may be disposed on the interlayer insulating layer ILD, and include a metal layer MTL. The data line DL may be formed through the same process as the source electrode SE (and the drain electrode DE) and the twelfth connection pattern CP12, shown in FIG. 3A, and may have the same material and structure as the source electrode SE (and the drain electrode DE) and the twelfth connection pattern CP12, shown in FIG. 3A. Therefore, overlapping descriptions will not be repeated. The data line DL may form a double-layer structure or a multi-layer structure so as to reduce line resistance (or contact resistance), and include at least one material selected from copper (Cu), molybdenum (Mo), tungsten (W), aluminum neodymium (AlNd), titanium (Ti), aluminum (Al), silver (Ag), and alloys thereof. The structure of the data line DL will be described later with reference to FIG. 8.

The data line DL, i.e., the metal layer MTL of the data line DL, which extends to the pad area PDA via the non-display area NA, may be disposed at a lower portion of the via layer VIA.

The pad PAD may include a first pad electrode ELTP and a second pad electrode CNEP.

The first pad electrode ELTP may be disposed on the via layer VIA (and the protective layer PSV) and the metal layer MTL, and the second pad electrode CNEP may be disposed on the first pad electrode ELTP. The insulating layer INS may be disposed over the second pad electrode CNEP and expose the second pad electrode CNEP.

The first pad electrode ELTP may be substantially identical or similar to the first and second electrodes ELT1 and ELT2 shown in FIG. 3A, and the second pad electrode CNEP may be substantially identical or similar to the first pixel electrode CNE1 and/or the second pixel electrode CNE2, shown n FIG. 3A or 3B. Therefore, overlapping descriptions will not be repeated. The first pad electrode ELTP may be formed through the same process as the first and second electrodes ELT1 and ELT2 shown in FIG. 3A, and may have the same material and structure as the first and second electrodes ELT1 and ELT2 shown in FIG. 3A. The second pad electrode CNEP may be formed through the same process as at least one of the first pixel electrode CNE1 and the second pixel electrode CNE2, which are shown in FIG. 3A or 3B, and include the same material as at least one of the first pixel electrode CNE1 and the second pixel electrode CNE2, which are shown in FIG. 3A or 3B. For example, the second pad electrode CNEP may include a transparent conductive material such as ITO or IGZO.

In embodiments, an uppermost layer of the first pad electrode ELTP may include tungsten oxide (WOₓ). The tungsten oxide (WOₓ) may include tungsten dioxide (WO₂) and tungsten trioxide (WO₃). A contact resistance (and a resistive-capacitance delay) between the first pad electrode ELTP and the second pad electrode CNEP (e.g., the second pad electrode CNEP including ITO) can be decreased, and a defect caused by the contact resistance can be reduced or prevented.

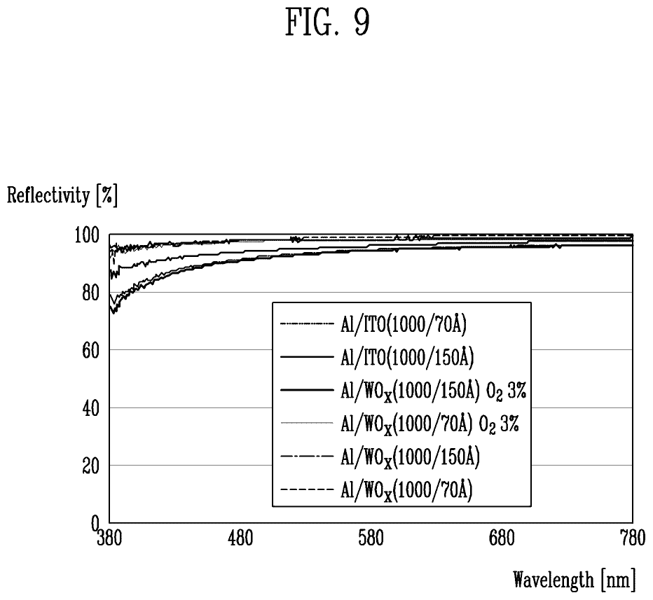

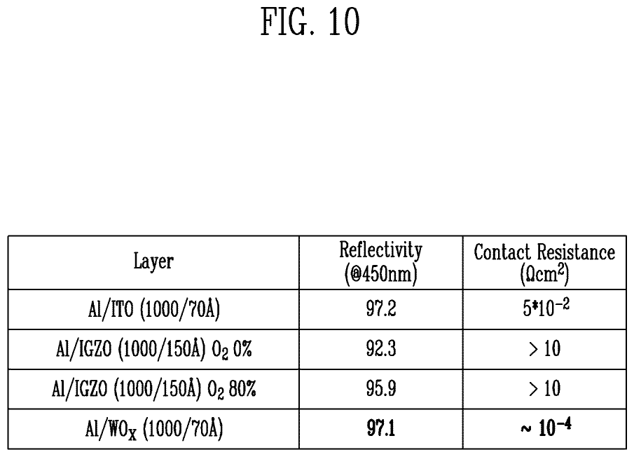

FIG. 7 is a schematic sectional view illustrating an embodiment of the first pad electrode shown in FIG. 6. FIG. 8 is a schematic sectional view illustrating an embodiment of the pad shown in FIG. 6. In FIG. 8, a pad PAD to which a first pad electrode ELTP shown in FIG. 7 is applied is illustrated. FIG. 9 is a schematic view illustrating a reflexibility of the first pad electrode shown in FIG. 6. In FIG. 9, reflexibilities of light according to materials and thicknesses of the first pad electrode ELTP (and the electrode ELT) shown in FIG. 6 are illustrated. FIG. 10 is a schematic view illustrating a contact resistance of the first pad electrode shown in FIG. 6. In FIG. 10, contact resistances according to materials constituting the first pad electrode ELTP (and the electrode ELT) shown in FIG. 6 are illustrated. For convenience of description, reflexibilities are further illustrated in FIG. 10.

The first and second electrodes ELT1 and ELT2 shown in FIGS. 3A and 3B and the first pad electrode ELTP shown in FIG. 6 may have the same material and structure. Therefore, for convenience of description, the first pad electrode ELTP will be described below. In other words, embodiments of the first pad electrode ELTP may be applied to the first and second electrodes ELT1 and ELT2 shown in FIGS. 3A and 3B.

First, referring to FIGS. 3A, 3B, 6, 7, and 8, each of a first pad electrode ELTP and an electrode ELT (i.e., the first and second electrodes ELT1 and ELT2 shown in FIGS. 3A and 3B) may have a multi-layer structure including a third layer ML3, a first layer ML1, and a second layer ML2 (or first to third metal layers), which are sequentially stacked on each other.

In embodiments, the first layer ML1 may include a material having a high reflexibility among conductive materials. For example, the first layer ML1 may include aluminum (Al). Each of the second layer ML2 and the third layer ML3 may include a material capable of preventing corrosion of the first layer ML1. For example, each of the second layer ML2 and the third layer ML3 may include tungsten oxide (WOₓ). For example, each of the first pad electrode ELTP and the electrode ELT may have a structure of WOₓ/Al/WOₓ.

The first layer ML1 (particularly, the first layer ML1 of the electrode ELT) including the aluminum (Al) may reflect light. The second layer ML2 including the tungsten oxide (WOₓ) may have an excellent characteristic in case that the second layer ML2 is in direct contact with the second pad electrode CNEP. The second layer ML2 may be simultaneously etched (e.g., dry-etched) with the first layer ML1. Thus, the first pad electrode ELTP (and the electrode ELT) can be readily formed (or patterned). Further, the second layer ML2 can prevent the first layer ML1 from being undesiredly eroded in a process of forming the first pad electrode ELTP. The third layer ML3 including the tungsten oxide (WOₓ) may prevent the first layer ML1 from being in direct contact with a metal layer MTL (or a metal layer MTL of a data line DL). For example, in case that the metal layer MTL includes copper (Cu), the third layer ML3 may prevent the first layer ML1 (e.g., the aluminum (AL)) and the copper (Cu) from being in direct contact with each other, and protect the copper (Cu) weak to corrosion.

In an embodiment, the first layer ML1 may include only aluminum (Al) (or pure-Al) instead of an aluminum alloy. For example, the first layer ML1 may not include any material except the aluminum (Al). The reflexibility (or reflective characteristic) of the electrode ELT can be improved by the first layer ML1.

In an embodiment, with respect to third direction DR3, a thickness TH2 of the second layer ML2 may be about 50 Å to about 300 Å, and a thickness TH1 of the first layer ML1 may be about 500 Å to about 2000 Å. The reflexibility (or reflective characteristic) of the electrode ELT can be further improved. Similar to the thickness TH2 of the second layer ML2, a thickness TH3 of the third layer ML3 may be about 50 Å to about 300 Å.

Referring to FIG. 9, the first pad electrode ELTP (or the electrode ELT) according to a first case and a second case may have a single-layer structure of aluminum (Al) and a thickness of 1000 Å.

In the first case, an ITO layer having a thickness of 70 Å may be disposed on the first pad electrode ELTP (i.e., Al/ITO (1000/70 Å)). As the wavelength becomes shorter, the reflexibility may become lower. However, in the first case, the first pad electrode ELTP (or the electrode ELT) may have a reflexibility of about 95% or more in a visible wavelength range (i.e., about 380 nm to about 780 nm).

In the second case, an ITO layer having a thickness of 150 Å may be disposed on the first pad electrode ELTP (i.e., Al/ITO (1000/150 Å)). In the second case, the first pad electrode ELTP (or the electrode ELT) may have a reflexibility of about 90% or more in the visible wavelength range.

The first pad electrode ELTP (or the electrode ELT) according to third to sixth cases may have a multi-layer structure of aluminum (Al) and tungsten oxide (WOₓ), and the thickness of an aluminum (Al) layer may be about 1000 Å.

The thickness of a tungsten oxide (WOₓ) layer of the first pad electrode ELTP (or the electrode ELT) according to the third case may be about 150 Å, and oxygen (O₂) may be added by about 3% in a sputtering process for forming the first pad electrode ELTP (i.e., Al/WOₓ (1000/150 Å) O₂ 3%). The first pad electrode ELTP (or the electrode ELT) according to the third case may have a reflexibility of about 70% or more in the visible wavelength range.

The thickness of a tungsten oxide (WOₓ) layer of the first pad electrode ELTP (or the electrode ELT) according to the fourth case may be about 70 Å, and oxygen (O₂) may be added by about 3% in the sputtering process for forming the first pad electrode ELTP (i.e., Al/WOₓ (1000/70 Å) O₂ 3%). The first pad electrode ELTP (or the electrode ELT) according to the fourth case may have a reflexibility of about 85% or more in the visible wavelength range.

The thickness of a tungsten oxide (WOₓ) layer of the first pad electrode ELTP (or the electrode ELT) according to the fifth case may be about 150 Å (i.e., Al/WOₓ (1000/150 Å)). The first pad electrode ELTP (or the electrode ELT) according to the fifth case may have a reflexibility of about 75% or more in the visible wavelength range.

The thickness of a tungsten oxide (WOₓ) layer of the first pad electrode ELTP (or the electrode ELT) according to the sixth case may be about 70 Å (i.e., Al/WOₓ (1000/70 Å)). The first pad electrode ELTP (or the electrode ELT) according to the sixth case may have a reflexibility of about 95% or more in the visible wavelength range.

As the thickness of the ITO layer or the tungsten oxide (WOₓ) layer becomes smaller, the reflexibility (or reflective characteristic) of the first pad electrode ELTP (or the electrode ELT) may become higher. The reflexibility of the first pad electrode ELTP (i.e., Al/ITO (1000/70 Å)) according to the first case and the reflexibility of the first pad electrode ELTP (i.e., Al/WOₓ (1000/70 Å)) according to the sixth case may be highest. The thickness of the tungsten oxide (WOₓ) layer (i.e., the thickness TH2 of the second layer ML2 shown in FIG. 7) may be about 300 Å or less by considering a required reference reflexibility of the first pad electrode ELTP (or light emission efficiency of the sub-pixel). The tungsten oxide (WOₓ) layer of the first pad electrode ELTP may be partially etched in a manufacturing process of the display device. For example, the tungsten oxide (WOₓ) layer of the first pad electrode ELTP may be dissolved or etched by tetramethylammonium hydroxide (TMAH) used in a cleaning process for removing a photoresistor. Therefore, the thickness of the tungsten oxide (WOₓ) layer of the first pad electrode ELTP may be about 50 Å or more by considering an etching margin.

Referring to FIG. 10, the first pad electrode ELTP (i.e., Al/ITO (1000/70 Å)) according to the first case may have a reflexibility of 97.2% with respect to a wavelength of 450 nm, and have a contact resistance of 5*10⁻² Ωcm². The first pad electrode ELTP (i.e., Al/WOₓ (1000/70 Å)) according to the sixth case may have a reflexibility of 97.1% with respect to a wavelength of 450 nm, and have a contact resistance of 5*10⁻⁴ Ωcm². The contact resistance may be a contact resistance between the first pad electrode ELTP and ITO. For example, in case that the first pad electrode ELTP includes a tungsten oxide (WOₓ) layer, the contact resistance can be considerably decreased while degradation of reflexibility is minimized.

In cases where an IGZO layer having a thickness of 150 Å instead of the ITO is disposed on the first pad electrode ELTP and oxygen (O₂) is used or is not used (i.e., Al/IGZO (1000/150 Å), O₂ 0%, Al/IGZO (1000/150 Å), O₂ 80%), degradation of reflexibility and an increase in contact resistance may be represented as shown in FIG. 10.

Like the first pad electrode ELTP (i.e., Al/ITO (1000/70 Å)) according to the first case, in case that an aluminum (Al) layer and an ITO layer are in contact with each other, the aluminum (Al) layer may be corroded or oxidized due to a standard reduction potential difference between aluminum (Al) and ITO. In case that the aluminum (Al) layer is exposed to the outside, the aluminum (Al) layer may be corroded by a solution (e.g., potassium hydroxide (KOH), TMAH or the like) used in the manufacturing process of the display device. In order to prevent corrosion of the aluminum (Al) layer, the first pad electrode ELTP (or the electrode ELT) may have a multi-layer structure such as Ti/Al/Ti or Mo/Al/Mo, but a contact resistance of a titanium (Ti) layer and a molybdenum (Mo) layer (i.e., a contact resistance with an ITO layer) may be increased.

Thus, the first pad electrode ELTP and the electrode ELT in accordance with the embodiments of the disclosure may include the tungsten oxide (WOₓ) layer on the aluminum (Al) layer, and accordingly, corrosion (or oxidation) of the aluminum (Al) layer can be prevented by the tungsten oxide (WOₓ) layer, and the contact resistance can be decreased.

Referring back to FIG. 8, the metal layer MTL of the data line DL may have a multi-layer structure including a sixth layer ML6, a fourth layer ML4, and a fifth layer ML5 (or fourth to sixth metal layers), which are sequentially stacked on each other. The fourth layer ML4 may include a material having a high electrical conductivity among conductive materials. For example, the fourth layer ML4 may include copper (Cu). Each of the sixth layer ML6 and the fifth layer ML5 may include a material capable of preventing corrosion of the fourth layer ML4. For example, each of the sixth layer ML6 and the fifth layer ML5 may include titanium (Ti). For example, the data line DL (and the source electrode SE (and the drain electrode DE) shown in FIG. 3A) and the twelfth connection pattern CP12 may have a structure of Ti/Cu/Ti.

The fifth layer ML5 along with the third layer ML3 may prevent the first layer ML1 and the fourth layer ML4 from being in direct contact with each other. For example, in case that the first layer ML1 includes aluminum (Al) and the fourth layer ML4 includes copper (Cu), the fifth layer ML5 may prevent the aluminum (Al) and the copper (Cu) from being in direct contact with each other. The sixth layer ML6 may be located under the fourth layer ML4 to prevent corrosion of the fourth layer ML4.

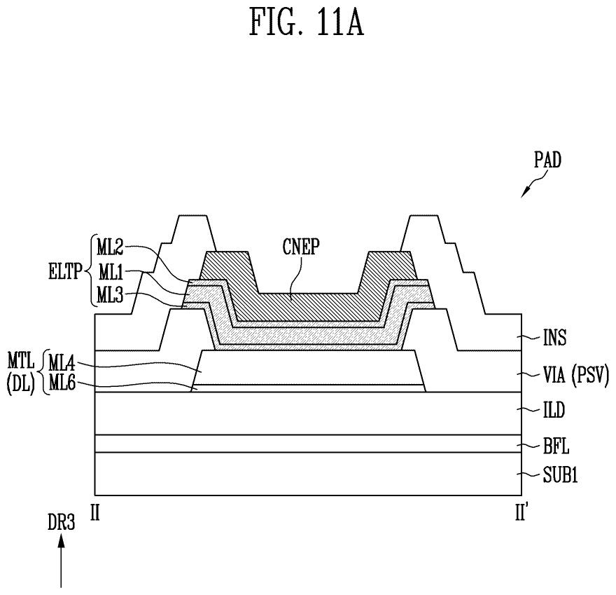

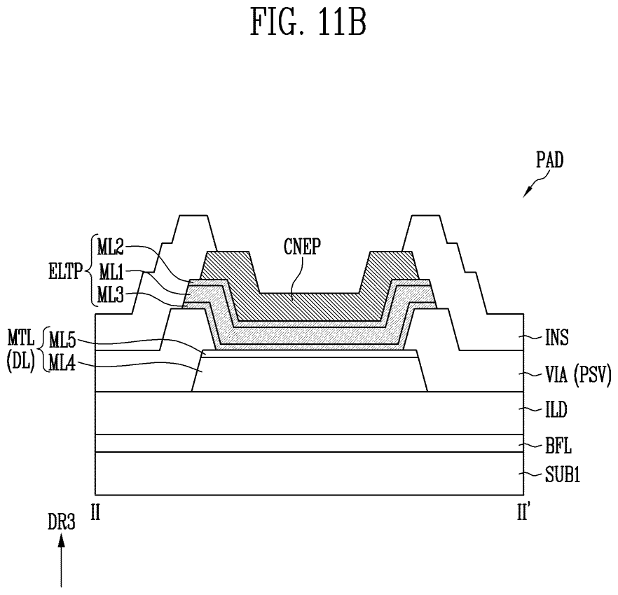

FIGS. 11A and 11B are schematic sectional views illustrating other embodiments of the pad shown in FIG. 6.

Referring to FIGS. 8, 11A, and 11B, the embodiments shown in FIGS. 11A and 11B may be substantially identical or similar to the embodiment shown in FIG. 8, except a structure of the metal layer MTL (or the metal layer MTL of the data line DL), and therefore, overlapping descriptions will not be repeated.

In an embodiment, as shown in FIG. 11A, the metal layer of the data line DL may include a sixth layer ML6 and a fourth layer ML4, which are sequentially stacked on each other, and may not include the fifth layer ML5 (see FIG. 8). For example, the sixth layer ML6 may include titanium (Ti), and the fourth layer ML4 may include copper (Cu). For example, the data lines DL (and the source electrode SE (and the drain electrode DE) shown in FIG. 3A) and the twelfth connection pattern CP12 may have a structure of Ti/Cu.

By the third layer ML3 including tungsten oxide (WOₓ), the first layer ML1 (e.g., aluminum (Al)) and the fourth layer ML4 (e.g., copper (Cu)) may be prevented from being in direct contact with each other. Therefore, the fifth layer ML5 (see FIG. 8) which functions similar to the third layer ML3 may be omitted.

In another embodiment, as shown in FIG. 11B, the metal layer MTL of the data line DL may include a fourth layer ML4 and a fifth layer ML5, which are sequentially stacked on each other, and may not include the sixth layer ML6 (see FIG. 8). For example, the fourth layer ML4 may include copper (Cu), and the fifth layer ML5 may include titanium (Ti). For example, the data lines DL (and the source electrode SE (and the drain electrode DE) shown in FIG. 3A) and the twelfth connection pattern CP12 may have a structure of Cu/Ti. For example, the metal layer MTL of the data line DL may have various multi-layer structures.

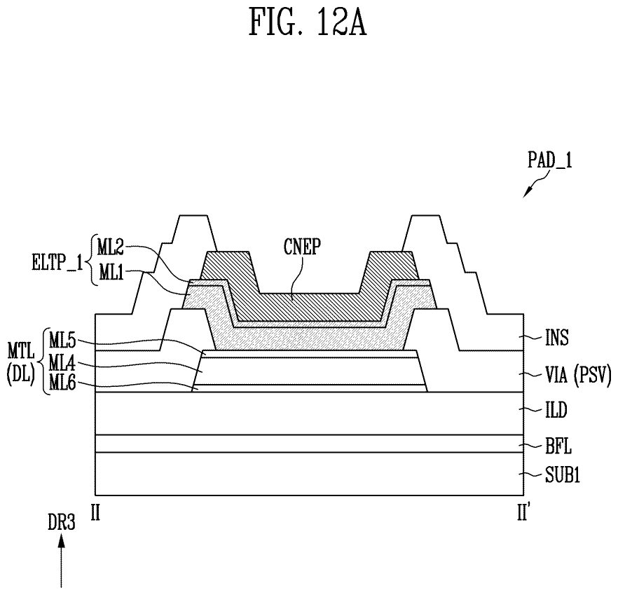

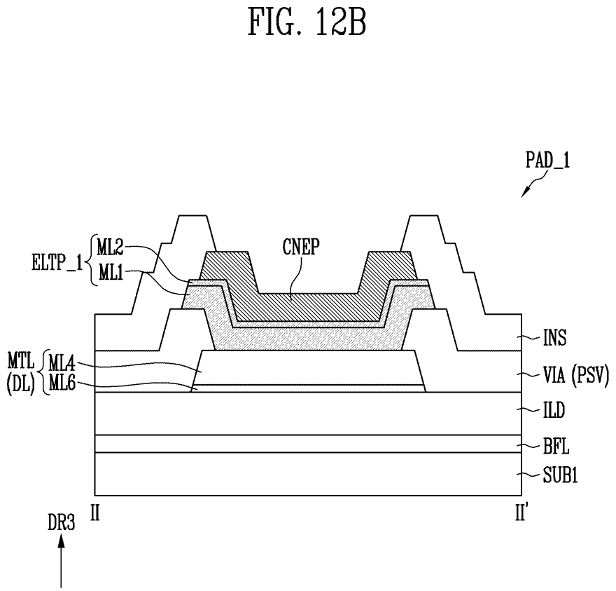

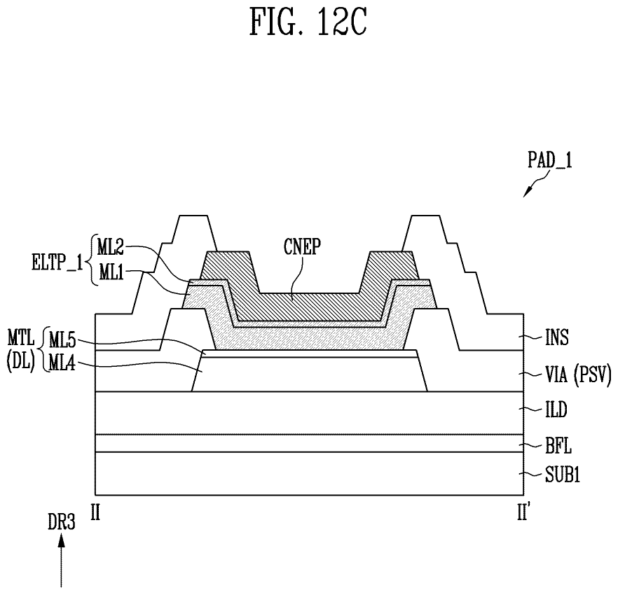

FIGS. 12A, 12B, and 12C are schematic sectional views illustrating other embodiments of the pad shown in FIG. 6.

Referring to FIGS. 8, 12A, 12B, and 12C, the embodiments shown in FIGS. 12A, 12B, and 12C may be substantially identical or similar to the embodiment shown in FIG. 8, except a structure of the first pad electrode ELTP and a structure of the metal layer MTL (or the metal layer MTL of the data line DL), and therefore, overlapping descriptions will not be repeated. The embodiments shown in FIGS. 12A, 12B, and 12C may be applied to the embodiments shown in FIGS. 3A and 3B (i.e., the first and second electrodes ELT1 and ELT2, the source electrode SE, and the like, which are shown in FIGS. 3A and 3B).

A pad PAD_1 may include a first pad electrode ELTP_1.

In embodiments, the first pad electrode ELTP_1 may have a multi-layer structure including a first layer ML1 and a second layer ML2, which are sequentially stacked on each other. The first pad electrode ELTP_1 may not include the third layer ML3 (see FIG. 8). The first layer ML1 may include aluminum (Al), and the second layer ML2 may include tungsten oxide (WOₓ). For example, the first pad electrode ELTP_1 may have a structure of Al/WOₓ.

In an embodiment, as shown in FIG. 12A, the metal layer MTL of the data line DL may have a multi-layer structure including a sixth layer ML6, a fourth layer ML4, and a fifth layer ML5 (or fourth to sixth metal layers), which are sequentially stacked on each other. For example, the fourth layer ML4 may include copper (Cu), and each of the fifth layer ML5 and the sixth layer ML6 may include titanium (Ti). For example, the data line DL (and the source electrode SE shown in FIG. 3A) and the twelfth connection pattern CP12 may have a structure of Ti/Cu/Ti.

By the fifth layer ML5 including titanium (Ti), the first layer ML1 (e.g., aluminum (Al)) and the fourth layer (ML4) (e.g., copper (Cu)) may be prevented from being in direct contact with each other. Therefore, the third layer ML3 (see FIG. 8) which functions similarly to the fifth layer ML5 may be omitted.

In another embodiment, as shown in FIG. 12B, the metal layer MTL of the data line DL may include a sixth layer ML6 and a fourth layer ML4, which are sequentially stacked on each other, and may not include the fifth layer ML5 (see FIG. 8). For example, the sixth layer ML6 may include titanium (Ti), and the fourth layer ML4 may include copper (Cu). For example, the data line DL (and the source electrode SE (and the drain electrode DE) shown in FIG. 3A) and the twelfth connection pattern CP12 may have a structure of Ti/Cu.

In still another embodiment, as shown in FIG. 12C, the metal layer MTL of the data line DL may include a fourth layer ML4 and a fifth layer ML5, which are sequentially stacked on each other, and may not include the sixth layer ML6 (see FIG. 8). For example, the fourth layer ML4 may include copper (Cu), and the fifth layer ML5 may include titanium (Ti). For example, the data line DL (and the source electrode SE (and the drain electrode DE) shown in FIG. 3A) and the twelfth connection pattern CP12 may have a structure of Cu/Ti.

As described above, the first pad electrode ELTP_1 may have a structure of Al/WOₓ, and the metal layer MTL of the data line DL may have various multi-layer structures.

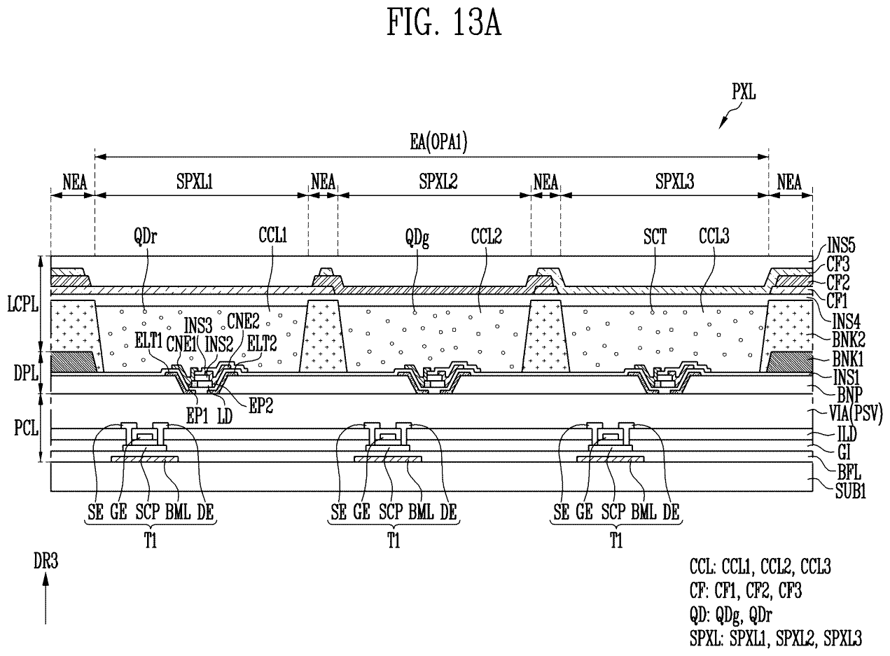

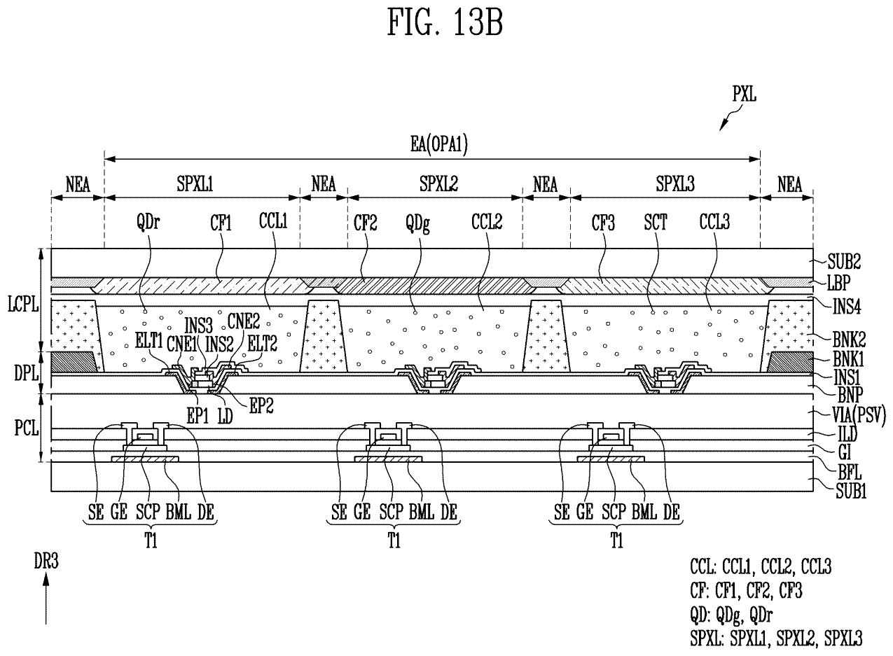

FIGS. 13A and 13B are schematic sectional views illustrating an embodiment of the pixel included in the display device shown in FIG. 1. FIG. 13B illustrates a modified example of FIG. 13A in relation to positions of color filters CF1 to CF3. For example, an embodiment in which the color filters CF1 to CF3 are located through a continuous process is disclosed in FIG. 13A, and an embodiment in which a second substrate SUB2 including the color filters CF1 to CF3 is located on the display element layer DPL through an adhesion process is disclosed in FIG. 13B. In relation to the embodiments shown in FIGS. 13A and 13B, portions different from those of the above-described embodiments (e.g., the embodiment shown in FIG. 3A) will be described to avoid redundancy.

Referring to FIGS. 3A and 13A, the sub-pixel SPXL (or the display device) may further include a light conversion layer LCPL disposed on the display element layer DPL.

The light conversion layer LCPL may further include a second bank BNK2, a color conversion layer CCL, and color filters CF1 to CF3.

The second bank BNK2 may be disposed on the display element layer DPL. The second bank BNK2 may be located in a non-emission area NEA, and be a structure defining a position at which the color conversion layer CCL is to be supplied.

The second bank BNK2 may include an organic material. In some embodiments, the second bank BNK2 may include a light blocking material. In an example, the second bank BNK2 may be a black matrix. In some embodiments, the second bank BNK2 may be configured to include at least one light blocking material and/or at least one reflective material. Thus, the second bank BNK2 may allow light emitted from the color conversion layer CCL to further advance in the third direction DR3 (or the image display direction of the display device), thereby improving light emission efficiency of the color conversion layer CCL (or the sub-pixel SPXL).

The color conversion layer CCL may be disposed on the display element layer DPL (or the light emitting element LD) in an area surrounded by the second bank BNK2.

The color conversion layer CCL may include color conversion particles QD (or wavelength conversion particles) corresponding to a specific color. In an example, the color conversion layer CCL may include color conversion particles QD for converting light of a first color (or first wavelength band), which is incident from the light emitting element LD, into light of a second color (specific color, or second wavelength band) and releasing the light having the converted wavelength.

In case that the first sub-pixel SPXL1 is a red pixel (or red sub-pixel), a first color conversion layer CCL1 of the first sub-pixel SPXL1 may include first color conversion particles QDr of a red quantum dot, which convert light of the first color, which is emitted from the light emitting element LD, into light of the second color, e.g., light of red.

In case that the second sub-pixel SPXL2 is a green pixel (or green sub-pixel), a second color conversion layer CCL2 of the second sub-pixel SPXL2 may include second color conversion particles QDg of a green quantum dot, which convert light of the first color, which is emitted from the light emitting element LD, into light of a third color, e.g., light of green.

In case that the third sub-pixel SPXL3 is a blue pixel (or blue sub-pixel), a third color conversion layer CCL3 of the third sub-pixel SPXL3 may include color conversion particles of a blue quantum dot, which convert light of the first color, which is emitted from the light emitting element LD, into light of a fourth color, e.g., light of blue.

In some embodiments, in case that the third sub-pixel SPXL3 is the blue pixel (or blue sub-pixel), and the light emitting element LD emits blue series light, the third sub-pixel SPXL3 may include a light scattering layer including light scattering particles SCT. The above-described light scattering layer may be omitted in some embodiments. In other embodiments, in case that the third sub-pixel SPXL3 is the blue pixel (or blue sub-pixel), transparent polymer may be provided instead of the third color conversion layer CCL3.

A fourth insulating layer INS4 may be disposed over the color conversion layer CCL and the second bank BNK2.

The fourth insulating layer INS4 may be entirely provided on the first substrate SUB1 to cover the second bank BNK2 and the color conversion layer CCL. The fourth insulating layer INS4 may include an inorganic material or an organic material. In some embodiments, the fourth insulating layer INS4 may totally reflect light emitted from the color conversion layer CCL (e.g., light advancing in an oblique direction) by using a refractive index difference between the fourth insulating layer INS4 and an adjacent component, and improve the light emission efficiency of the sub-pixel SPXL. To this end, the fourth insulating layer INS4 may reduce a step difference occurring due to components disposed on the bottom thereof, and have a flat surface.

In some embodiments, the fourth insulating layer INS4 may reduce a step difference occurring due to components disposed on the bottom thereof, and have a flat surface.

In an embodiment, first and second capping layers may be disposed on the top and the bottom of the fourth insulating layer INS4. The first and second capping layers may include an inorganic material. The first and second capping layers may prevent moisture (or a solution used in a subsequent process) from infiltrating into lower components (e.g., the color conversion layer CCL and the fourth insulating layer INS4).

A color filter layer may be disposed on the fourth insulating layer INS4.

Referring to FIG. 13B, the color filter layer may include a color filter CF corresponding to a color of each of adjacent sub-pixels. For example, a first color filter CF1 may be disposed on the first color conversion layer CCL1 of the first sub-pixel SPXL1, a second color filter CF2 may be disposed on the second color conversion layer CCL2 of the second sub-pixel SPXL2, and a third color filter CF3 may be disposed on the third color conversion layer CCL3 of the third sub-pixel SPXL3. Each of the first, second, and third color filters CF1, CF2, and CF3 may include a color filter material for allowing light of a specific color, which is converted in the color conversion layer CCL, to be selectively transmitted therethrough. In an example, the first color filter CF1 may be a red color filter, the second color filter CF2 may be a green color filter, and the third color filter CF3 may be a blue color filter. The above-described color filter CF may be provided on a surface of the fourth insulating layer INS4 to correspond to the color conversion layer CCL.

The first, second, and third color filters CF1, CF2, and CF3 may be disposed in the non-emission area NEA to overlap one another, to block light interference between adjacent sub-pixels. In some embodiments, a separate light blocking pattern instead of a stacked structure of the first, second, and third color filters CF1, CF2, and CF3 may be disposed in the non-emission area NEA.

A fifth insulating layer INS5 may be disposed over the color filter layer. The fifth insulating layer INS5 may include an inorganic material or an organic material. The fifth insulating layer INS5 may entirely cover components located on the bottom thereof, thereby blocking moisture, humidity or the like from being introduced into the color filter layer and the display element layer DPL from the outside. In an embodiment, the fifth insulating layer INS5 may be formed as a multi-layer. For example, the fifth insulating layer INS5 may include at least two inorganic layers and at least one organic layer interposed between the at least two inorganic layers. However, the material and/or structure of the fifth insulating layer INS5 may be variously changed. In some embodiments, at least one overcoat layer, at least one filler layer, and/or an upper substrate may be further disposed on the top of the fifth insulating layer INS5.

Although a case where the color filter layer is directly formed on the color conversion layer CCL has been described in the above-described embodiment, the disclosure is not limited thereto. In some embodiments, the color filter layer may be formed on a separate substrate, e.g., the second substrate SUB2 as shown in FIG. 7C, to be coupled to the color conversion layer CCL through an adhesive material. For example, the adhesive material may be an optically clear adhesive, but the disclosure is not limited thereto.

The second substrate SUB2 (or upper substrate) may constitute an encapsulation substrate and/or a window member of the display device. The second substrate SUB2 may be configured with the same material as the first substrate SUB1, or be configured with a material different from the material of the first substrate SUB1.

Referring to FIG. 13B, a color filter CF may be disposed under the second substrate SUB2 to face the display element layer DPL.

A light blocking pattern LBP may be located adjacent to the color filter CF. The light blocking pattern LBP may be disposed under the second substrate SUB2 to correspond to the non-emission area NEA. The light blocking pattern LBP may be a black matrix.

In case that the sub-pixel SPXL includes a light conversion layer LCPL on the display element layer DPL, i.e., in case that the sub-pixel SPXL includes a color conversion layer CCL and a color filter, which are disposed over the light emitting element LD, light having excellent color reproducibility is emitted through the color conversion layer CCL and the color filter CF, and the light emission efficiency of the sub-pixel SPXL can be improved.

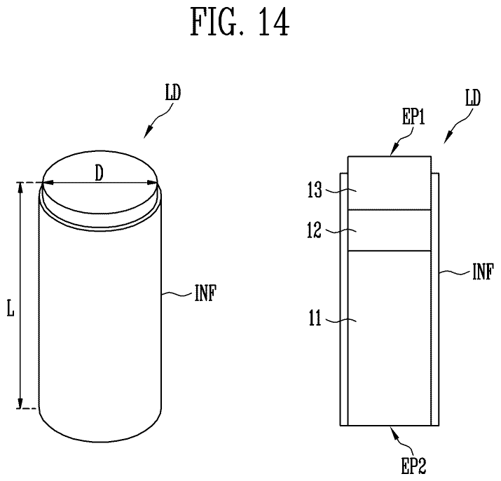

FIG. 14 is a schematic view illustrating a light emitting element in accordance with an embodiment of the disclosure. Although a pillar-shaped light emitting element LD is illustrated in FIG. 14, the kind and/or shape of the light emitting element LD is not limited thereto.

Referring to FIG. 14, the light emitting element LD may include a first semiconductor layer 11, a second semiconductor layer 13, and an active layer 12 interposed between the first and second semiconductor layers 11 and 13. In an example, in case that an extending direction of the light emitting element LD is a length L direction, the light emitting element LD may include the first semiconductor layer 11, the active layer 12, and the second semiconductor layer 13, which are sequentially stacked on each other along the length L direction.

The light emitting element LD may be provided in a pillar shape extending along a direction. The light emitting element LD may have a first end portion EP1 and a second end portion EP2. One of the first and second semiconductor layers 11 and 13 may be disposed at the first end portion EP1 of the light emitting element LD. The other of the first and second semiconductor layers 11 and 13 may be disposed at the second end portion EP2 of the light emitting element LD.

In some embodiments, the light emitting element LD may be a light emitting element manufactured in a pillar shape through an etching process, or the like. In this specification, the term “pillar shape” may include a rod-like shape or bar-like shape, which is long in the length L direction (i.e., its aspect ratio is greater than 1), such as a cylinder or a polyprism, and the shape of its section is not particularly limited. For example, a length L of the light emitting element LD may be greater than a diameter D (or a width of a cross-section) of the light emitting element LD.

The light emitting element LD may have a size small to a degree of nanometer scale to micrometer scale. In an example, the light emitting element LD may have a diameter D (or width) in a range of nanometer scale to micrometer scale and/or a length L in a range of nanometer scale to micrometer scale. For example, the length L of the light emitting element LD may be about 1 μm to about 10 μm or about 3.5 μm to about 4 μm, and the diameter D of the light emitting element LD may be about 0.1 μm to about 1 μm or about 500 nm to about 600 nm. However, the size of the light emitting element LD is not limited thereto, and the size of the light emitting element LD may be variously changed according to design conditions of various types of devices, e.g., a display device, and the like, which use, as a light source, a light emitting device using the light emitting element LD.

The first semiconductor layer 11 may be a first conductivity type semiconductor layer. For example, the first semiconductor layer 11 may include an n-type semiconductor layer. In an example, the first semiconductor layer 11 may include at least one semiconductor material among InAlGaN, GaN, AlGaN, InGaN, AlN, and InN, and include an n-type semiconductor layer doped with a first conductivity type dopant such as Si, Ge or Sn. However, the material constituting the first semiconductor layer 11 is not limited thereto. The first semiconductor layer 11 may be configured with various materials.

The active layer 12 may be formed on the first semiconductor layer 11, and may be formed in a single-quantum well structure or a multi-quantum well structure. The position of the active layer 12 may be variously changed according to a kind of the light emitting element LD.

A clad layer (not shown) doped with a conductive dopant may be formed on the top and/or the bottom of the active layer 12. In an example, the clad layer may be formed as an AlGaN layer or InAlGaN layer. In some embodiments, a material such as AlGaN or AlInGaN may be used to form the active layer 12. The active layer 12 may be configured with various materials.

The second semiconductor layer 13 may be formed on the active layer 12, and may include a semiconductor layer having a type different from that of the first semiconductor layer 11. For example, the second semiconductor layer 13 may include a p-type semiconductor layer. In an example, the second semiconductor layer 13 may include at least one semiconductor material among InAlGaN, GaN, AlGaN, InGaN, AlN, and InN, and include a p-type semiconductor layer doped with a second conductivity type dopant such as Mg. However, the material constituting the second semiconductor layer 13 is not limited thereto. The second semiconductor layer 13 may be configured with various materials.

In case that a voltage which is a threshold voltage or more is applied to both ends of the light emitting element LD, the light emitting element LD may emit light as electron-hole pairs are combined in the active layer 12. The light emission of the light emitting element LD may be controlled by using such a principle, so that the light emitting element LD can be used as a light source for various light emitting devices, including a pixel of a display device.

The light emitting element LD may further include an insulative film INF provided on a surface thereof. The insulative film INF may be formed on the surface of the light emitting element LD to surround an outer circumferential surface of at least the active layer 12. The insulative film INF may further surround an area of each of the first and second semiconductor layers 11 and 13.

In some embodiments, the insulative film INF may expose both the end portions of the light emitting element LD, which have different polarities. For example, the insulative film INF may expose an end of each of the first and second semiconductor layers 11 and 13 located at the first and second end portions EP1 and EP2 of the light emitting element LD. In another embodiment, the insulative film INF may expose a side portion of each of the first and second semiconductor layers 11 and 13 adjacent to the first and second end portions EP1 and EP2 of the light emitting element LD, which have different polarities.

In some embodiments, the insulative film INF may be configured as a single layer or a multi-layer (e.g., a double layer configured with aluminum oxide (AlOₓ) and silicon oxide (SiOₓ)), including at least one insulating material among silicon oxide (SiOₓ), silicon nitride (SiNₓ), silicon oxynitride (SiOₓN_{y}), aluminum oxide (AlOₓ), and titanium oxide (TiOₓ), but the disclosure is not limited thereto. For example, in accordance with another embodiment, the insulative film INF may be omitted.

In case that the insulative film INF is provided to cover the surface of the light emitting element LD, particularly, the outer circumferential surface of the active layer 12, the active layer 12 can be prevented from being short-circuited with a first pixel electrode, a second pixel electrode, or the like, which will be described later. Accordingly, the electrical stability of the light emitting element LD can be ensured.

In case that the insulative film INF is provided on the surface of the light emitting element LD, a surface defect of the light emitting element LD can be minimized, thereby improving the lifetime and efficiency of the light emitting element LD. Even in case that light emitting elements LD are densely disposed, an unwanted short circuit can be prevented from occurring between the light emitting elements LD.

In an embodiment, the light emitting element LD may further include an additional component in addition to the first semiconductor layer 11, the active layer 12, the second semiconductor layer 13, and/or the insulative film INF surrounding the same. For example, the light emitting element LD may additionally include at least one phosphor layer, at least one active layer, at least one semiconductor layer, and/or at least one electrode layer, which may be disposed at an end of the first semiconductor layer 11, the active layer 12, and/or the second semiconductor layer 13. In an example, a contact electrode layer may be disposed at each of the first and second end portions EP1 and EP2 of the light emitting element LD. Although the pillar-shaped light emitting element LD has been shown in FIG. 14, the kind, structure, and/or shape of the light emitting element LD may be variously changed. For example, the light emitting element LD may be formed in a core-shell structure having a polypyramid shape.

A light emitting device including the above-described light emitting element LD may be used in various kinds of devices which require a light source, including a display device. For example, multiple light emitting elements LD may be disposed in each pixel of a display panel, and be used as a light source of each pixel. However, the application field of the light emitting element LD is not limited to the above-described example. For example, the light emitting element LD may be used in other types of devices that require a light source, such as a lighting device.

In a display device in accordance with the disclosure, an electrode (or first pad electrode) in contact with a pixel electrode (or second pad electrode) may have a multi-layer structure, and an uppermost layer of the electrode (or first pad electrode) may include tungsten oxide (WOₓ). The tungsten oxide (WOₓ) can prevent corrosion of a lower layer (e.g., aluminum (Al)) of the electrode (or first pad electrode), and decrease a contact resistance between the pixel electrode (or second pad electrode) and the electrode (or first pad electrode). Thus, a defect caused by the contact resistance or the like can be reduced or prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure.

What is claimed is:

1. A display device, comprising:
a first electrode and a second electrode that are disposed on a substrate and spaced apart from each other;
a light emitting element disposed between the first electrode and the second electrode;
a first pixel electrode disposed on the first electrode, the first pixel electrode being electrically connected to a first end portion of the light emitting element and the first electrode; and
a second pixel electrode disposed on the second electrode, the second pixel electrode being electrically connected to a second end portion of the light emitting element, wherein
each of the first electrode and the second electrode has a multi-layer structure including a first layer and a second layer disposed on the first layer,
the first layer includes a metal reflecting light, and
the second layer includes tungsten oxide.

2. The display device of claim 1, wherein
the first pixel electrode includes at least one of indium tin oxide (ITO), indium zinc oxide (IZO), zinc oxide (ZnOₓ), and indium gallium zinc oxide (IGZO), and
the first pixel electrode is in direct contact with the second layer of the first electrode.

3. The display device of claim 1, wherein
the first layer includes aluminum, and
the first layer does not include any alloy.

4. The display device of claim 1, wherein the second layer has a thickness in a range of about 50 Å to about 300 Å.

5. The display device of claim 4, wherein the first layer has a thickness in a range of about 500 Å to about 2000 Å.

6. The display device of claim 1, wherein
each of the first electrode and the second electrode further includes a third layer disposed under the first layer, and
the third layer and the first layer include a same material.

7. The display device of claim 6, further comprising:
an insulating layer disposed under the first electrode and the second electrode; and
a metal layer disposed between the substrate and the insulating layer,
wherein the first electrode is in electrical contact with the metal layer through a contact hole penetrating the insulating layer.

8. The display device of claim 7, wherein
the metal layer has a multi-layer structure including a fourth layer and a fifth layer disposed on the fourth layer,
the fourth layer includes a material having an electrical conductivity higher than an electrical conductivity of the fifth layer, and
the fifth layer of the metal layer is in direct contact with the third layer of the first electrode.

9. The display device of claim 7, wherein
the metal layer has a multi-layer structure including a fourth layer and a sixth layer disposed under the fourth layer,
the fourth layer includes a material having an electrical conductivity higher than an electrical conductivity of the sixth layer, and
the fourth layer of the metal layer is in direct contact with the third layer of the first electrode.

10. The display device of claim 1, further comprising:
an insulating layer disposed under the first electrode and the second electrode; and
a metal layer disposed between the substrate and the insulating layer,
wherein the first electrode is in electrical contact with the metal layer through a contact hole penetrating the insulating layer.

11. The display device of claim 10, wherein
the metal layer has a multi-layer structure including a fourth layer and a fifth layer disposed on the fourth layer,
the fourth layer includes a material having an electrical conductivity higher than an electrical conductivity of the fifth layer, and
the fifth layer of the metal layer is in direct contact with the first layer of the first electrode.

12. The display device of claim 1, further comprising:
a color conversion layer disposed above the light emitting element, the color conversion layer converting a wavelength of light incident from the light emitting element.

13. A display device, comprising:
a pixel disposed in a display area; and
a pad disposed in a non-display area located at a side of the display area, wherein
the pad includes:
a first pad electrode disposed on a metal layer; and
a second pad electrode disposed on the first pad electrode,
the first pad electrode has a multi-layer structure including a first layer and a second layer disposed on the first layer,
the first layer includes a metal reflecting light, and
the second layer includes tungsten oxide.

14. The display device of claim 13, wherein
the second pad electrode includes at least one of indium tin oxide (ITO), indium zinc oxide (IZO), zinc oxide (ZnOₓ), and indium gallium zinc oxide (IGZO), and
the second pad electrode is in direct contact with the second layer of the first pad electrode.

15. The display device of claim 13, wherein
the first layer includes aluminum, and
the first layer does not include any alloy.

16. The display device of claim 13, wherein the second layer has a thickness in a range of about 50 Å to about 300 Å.

17. The display device of claim 16, wherein the first layer has a thickness in a range of about 500 Å to about 2000 Å.

18. The display device of claim 13, wherein
the first pad electrode further includes a third layer located under the first layer, and
the third layer and the first layer include a same material.

19. The display device of claim 18, wherein
the metal layer has a multi-layer structure including a fourth layer and a fifth layer disposed on the fourth layer,
the fourth layer includes a material having an electrical conductivity higher than an electrical conductivity of the fifth layer, and
the fifth layer of the metal layer is in direct contact with the third layer of the first pad electrode.

20. The display device of claim 18, wherein
the metal layer has a multi-layer structure including a fourth layer and a sixth layer disposed under the fourth layer,
the fourth layer includes a material having an electrical conductivity higher than an electrical conductivity of the sixth layer, and
the fourth layer of the metal layer is in direct contact with the third layer of the first pad electrode.
